(19) United States
(12) Patent Application Publication
(10) Pub. No.: US 2026/0182176 A1
(43) Pub. Date: Jun. 25, 2026

(54) Display Substrate and Display Apparatus

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventors: Wenzhe CAI, Beijing (CN); Jia LIU, Beijing (CN); Rong WANG, Beijing (CN); Yao HUANG, Beijing (CN); Qiwei WANG, Beijing (CN); Xiangdan DONG, Beijing (CN)

(21) Appl. No.: 18/842,814

(22) PCT Filed: Sep. 26, 2023
(86) PCT No.: PCT/CN2023/121688

§ 371 Date: Aug. 30, 2024

(51) Int. Cl. H10K 59/131; H10D 86/60

(52) U.S. Cl. CPC H10K 59/131; H10D 86/60

(57) ABSTRACT

A display substrate and a display apparatus are provided. The display substrate includes a plurality of circuit units constituting a plurality of unit rows and a plurality of unit columns, a circuit unit includes a pixel drive circuit and a control line, the pixel drive circuit includes a drive transistor, a first light emitting control transistor, and a second light emitting control transistor, a second electrode of the first light emitting control transistor is connected to a first electrode of the drive transistor, a first electrode of the second light emitting control transistor is connected to a second electrode of the drive transistor, the first light emitting control transistor and the second light emitting control transistor are connected to different control lines; the first light emitting control transistor and the second light emitting control transistor are respectively disposed at two sides of the drive transistor in a unit column direction.

### CROSS-REFERENCE TO RELATED APPLICATION

The present application is a U.S. National Phase Entry of International Application PCT/CN2023/121688 having an international filing date of Sep. 26, 2023, and entitled “Display Substrate and Display Apparatus”, the contents of which should be interpreted as being incorporated herein by reference.

### TECHNICAL FIELD

The present disclosure relates to, but is not limited to, the field of display technologies, and more particularly, to a display substrate and a display apparatus.

### BACKGROUND

An Organic Light Emitting Diode (OLED for short) and a Quantum dot Light Emitting Diode (QLED for short) are active light emitting display devices and have advantages such as self-luminescence, wide viewing angle, high contrast ratio, low power consumption, very high response speed, lightness and thinness, flexibility, and low cost. With constant development of display technologies, a display apparatus (Flexible Display) in which an OLED or a QLED is used as a light emitting device and signal control is performed through a Thin Film Transistor (TFT) has become a mainstream product in the field of display at present.

### SUMMARY

The following is a summary of subject matter described herein in detail. This summary is not intended to limit the protection scope of claims.

In one aspect, the present disclosure provides a display substrate including a plurality of circuit units constituting a plurality of unit rows and a plurality of unit columns, at least one circuit unit includes a pixel drive circuit and at least one control line configured to provide a light emitting control signal to the pixel drive circuit; in at least one circuit unit, the pixel drive circuit at least includes a drive transistor, a first light emitting control transistor, and a second light emitting control transistor, wherein a first electrode of the first light emitting control transistor is connected to a first power supply line, a second electrode of the first light emitting control transistor is connected to a first electrode of the drive transistor, and a first electrode of the second light emitting control transistor is connected to a second electrode of the drive transistor; the first light emitting control transistor and the second light emitting control transistor are connected to different control lines, and the first light emitting control transistor and the second light emitting control transistor are respectively disposed at two sides of the drive transistor in a unit column direction.

In an exemplary implementation, the at least one control line includes a first signal line and a second signal line, and the first light emitting control transistor is connected to the first signal line and the second light emitting control transistor is connected to the second signal line, and the first signal line and the second signal line are respectively disposed at two sides of the drive transistor in the unit column direction.

In an exemplary implementation, the display substrate includes a plurality of conductive layers in a direction perpendicular to the display substrate, and the first signal line and the second signal line are disposed in different conductive layers.

In an exemplary implementation, the second light emitting control transistor at least includes a second gate, the second gate and the first signal line are disposed in a same conductive layer, and the second gate and the second signal line are disposed in different conductive layers.

In an exemplary implementation, the pixel drive circuit further includes a compensation transistor, a gate electrode of the compensation transistor is connected to a first scan signal line, a first electrode of the compensation transistor is connected to a gate electrode of the drive transistor through a first connection electrode, and a second electrode of the compensation transistor is connected to the second electrode of the drive transistor and the first electrode of the second light emitting control transistor respectively; an orthographic projection of the first connection electrode on a plane of the display substrate is at least partially overlapped with an orthographic projection of the first signal line on the plane of the display substrate, and the orthographic projection of the first connection electrode on the plane of the display substrate is at least partially overlapped with an orthographic projection of the first scan signal line on the plane of the display substrate.

In an exemplary implementation, the compensation transistor at least includes a compensation active layer, the second light emitting control transistor at least includes a second light emitting control active layer, and a second region of the compensation active layer is connected to a first region of the second light emitting control active layer through a fifth connection electrode; in a direction perpendicular to the display substrate, the display substrate at least includes at least one semiconductor layer and at least one conductive layer, the compensation active layer and the second light emitting control active layer are disposed in the semiconductor layer, and the fifth connection electrode is disposed in the conductive layer.

In an exemplary implementation, the pixel drive circuit further includes a data writing transistor, a first electrode of the data writing transistor is connected to a data signal line, a second electrode of the data writing transistor is connected to the first electrode of the drive transistor, and the data writing transistor and the compensation transistor are respectively disposed at two sides of the drive transistor in the unit column direction.

In an exemplary implementation, the at least one control line includes a light emitting signal line, the light emitting signal line is connected to the second light emitting control transistor in a present unit row, and the light emitting signal line is connected to a first light emitting control transistor in a next unit row.

In an exemplary implementation, the first light emitting control transistor at least includes a first gate, the second light emitting control transistor at least includes a second gate of the second light emitting control transistor, the light emitting signal line is connected to the second gate in the present unit row, and the light emitting signal line is connected to the first light emitting control transistor in the next unit row through a light emitting signal connection line.

In an exemplary implementation, in a direction perpendicular to the display substrate, the display substrate includes a plurality of conductive layers, the first gate of the first light emitting control transistor and the second gate of the second light emitting control transistor are disposed in a same conductive layer, the first gate and the light emitting signal line are disposed in different conductive layers, the first gate and the light emitting signal connection line are disposed in different conductive layers, and the light emitting signal connection line and the light emitting signal line are disposed in different conductive layers.

In an exemplary implementation, the plurality of conductive layers at least includes a first conductive layer, a second conductive layer, a third conductive layer, and a fourth conductive layer disposed sequentially on a base substrate along a direction away from the base substrate, the first gate and the second gate are disposed in the first conductive layer, the light emitting signal line is disposed in the third conductive layer, the light emitting signal line is connected to the second gate through a via, the light emitting signal connection line is disposed in the fourth conductive layer, a first end of the light emitting signal connection line is connected to the light emitting signal line in the present unit row through a via, and a second end of the light emitting signal connection line is connected to the first gate in the next unit row through a via.

In an exemplary implementation, the plurality of conductive layers further includes a fifth conductive layer disposed on a side of the fourth conductive layer away from the base substrate, the first power supply line is disposed in the fifth conductive layer, and an orthographic projection of the first power supply line on the plane of the display substrate is at least partially overlapped with an orthographic projection of the light emitting signal connection line on the plane of the display substrate.

In an exemplary implementation, at least one circuit unit further includes a first initial signal line extending along the unit row direction and a first connection line extending along the unit column direction, the first initial signal line is configured to provide a first initial signal to the pixel drive circuit, the first initial signal line and the first connection line are connected to form a net-like connecting structure for transmitting the first initial signal.

In an exemplary implementation, an orthographic projection of the first connection line on the plane of the display substrate is not overlapped with an orthographic projection of a gate electrode of the drive transistor on the plane of the display substrate.

In an exemplary implementation, the pixel drive circuit further includes a compensation transistor, an active layer of the compensation transistor and an active layer of the drive transistor are connected to each other by an active connection line, an orthographic projection of the first connection line on the plane of the display substrate and an orthographic projection of the active connection line on the plane of the display substrate are at least partially not overlapped.

In an exemplary implementation, at least one circuit unit further includes a second initial signal line extending along the unit row direction and a second connection line extending along the unit column direction, the second initial signal line is configured to provide a second initial signal to the pixel drive circuit, the second initial signal line and the second connection line are connected to form a net-like connecting structure for transmitting the second initial signal.

In an exemplary implementation, an orthographic projection of the second connection line on the plane of the display substrate is not overlapped with an orthographic projection of a gate electrode of the drive transistor on the plane of the display substrate.

In an exemplary implementation, the pixel drive circuit further includes a compensation transistor, an active layer of the compensation transistor and an active layer of the drive transistor are connected to each other by an active connection line, an orthographic projection of the second connection line on the plane of the display substrate and an orthographic projection of the active connection line on the plane of the display substrate are at least partially not overlapped.

In an exemplary implementation, at least one circuit unit further includes a third connection line extending along the unit row direction and a second power supply line extending along the unit column direction, and the second power supply line and the third connection line are connected to form a net-like connecting structure for transmitting a second power supply signal.

In an exemplary implementation, an orthographic projection of the second power supply line on the plane of the display substrate is not overlapped with an orthographic projection of a gate electrode of the drive transistor on the plane of the display substrate.

In an exemplary implementation, the pixel drive circuit further includes a compensation transistor, an active layer of the compensation transistor and an active layer of the drive transistor are connected to each other by an active connection line, and an orthographic projection of the second power supply line on the plane of the display substrate and an orthographic projection of the active connection line on the plane of the display substrate are at least partially not overlapped.

In an exemplary implementation, the pixel drive circuit further includes a storage capacitor and a first capacitor; the storage capacitor includes a first plate and a second plate, an orthographic projection of the first plate on the plane of the display substrate is at least partially overlapped with an orthographic projection of the second plate on the plane of the display substrate, the first plate serves as a gate electrode of the drive transistor, and the second plate is connected to the first power supply line; the first capacitor includes a third plate and a fourth plate, an orthographic projection of the third plate on the plane of the display substrate is at least partially overlapped with an orthographic projection of the fourth plate on the plane of the display substrate, the third plate is respectively connected to the first electrode of the drive transistor and the second electrode of the first light emitting control transistor, and the fourth plate is connected to the first power supply line.

In an exemplary implementation, in a direction perpendicular to the display substrate, the display substrate at least includes a semiconductor layer, a first conductive layer, and a second conductive layer disposed sequentially on the base substrate along a direction away from the base substrate, the third plate is disposed in the semiconductor layer, the first plate is disposed in the first conductive layer, and the second plate and the fourth plate are disposed in the second conductive layer.

In another aspect, the present disclosure further provides a display apparatus, including the display substrate described above.

Other aspects of the present disclosure may be comprehended after the drawings and the detailed descriptions are read and understood.

### BRIEF DESCRIPTION OF DRAWINGS

Accompany drawings are used to provide understanding of technical solution of the present disclosure, and form a part of the specification. The accompany drawings and embodiments of the present disclosure are used to explain the technical solution of the present disclosure, and do not form limitations on the technical solution of the present disclosure.

FIG. 1 is a schematic diagram of a structure of a display apparatus.

FIG. 2 is a schematic diagram of a planar structure of a display substrate.

FIG. 3 is a schematic diagram of a sectional structure of a display substrate.

FIG. 4 is an equivalent circuit diagram of a pixel drive circuit according to an exemplary embodiment of the present disclosure.

FIG. 5 is a schematic diagram of a structure of a display substrate according to an exemplary embodiment of the present disclosure.

FIG. 6 is a schematic diagram of a display substrate after a pattern of a semiconductor layer is formed, according to the present disclosure.

FIGS. 7A and 7B are schematic diagrams of a display substrate after a pattern of a first conductive layer is formed, according to the present disclosure.

FIGS. 8A and 8B are schematic diagrams of a display substrate after a pattern of a second conductive layer is formed, according to the present disclosure.

FIG. 9 is a schematic diagram of a display substrate after a pattern of a fourth insulation layer is formed, according to the present disclosure.

FIG. 10A and FIG. 10B are schematic diagrams of a display substrate after a pattern of a third conductive layer is formed, according to the present disclosure.

FIG. 11 is a schematic diagram of a display substrate after a pattern of a first planarization layer is formed according to the present disclosure.

FIG. 12A and FIG. 12B are schematic diagrams of a display substrate after a pattern of a fourth conductive layer is formed according to the present disclosure.

FIGS. 12C to 12E are schematic diagrams of net-like connecting structures for a first initial signal and a second initial signal according to the present disclosure.

FIG. 13 is a schematic diagram of a display substrate after a pattern of a second planarization layer is formed according to the present disclosure.

FIG. 14A and FIG. 14B are schematic diagrams of a display substrate after a pattern of an anode conductive layer is formed according to the present disclosure.

FIG. 15 is a schematic diagram of a display substrate after a pattern of a pixel definition layer is formed according to the present disclosure.

FIG. 16 is an equivalent circuit diagram of another pixel drive circuit according to an exemplary embodiment of the present disclosure.

FIG. 17 is a schematic diagram of a structure of another display substrate according to an exemplary embodiment of the present disclosure.

FIG. 18 is a schematic diagram of another display substrate after a pattern of a semiconductor layer is formed, according to the present disclosure.

FIGS. 19A and 19B are schematic diagrams of another display substrate after a pattern of a first conductive layer is formed, according to the present disclosure.

FIGS. 20A and 20B are schematic diagrams of another display substrate after a pattern of a second conductive layer is formed, according to the present disclosure.

FIG. 21 is a schematic diagram of another display substrate after a pattern of a fourth insulation layer is formed, according to the present disclosure.

FIGS. 22A and 22B are schematic diagrams of another display substrate after a pattern of a third conductive layer is formed, according to the present disclosure.

FIG. 23 is a schematic diagram of another display substrate after a pattern of a first planarization layer is formed according to the present disclosure.

FIG. 24A and FIG. 24B are schematic diagrams of another display substrate after a pattern of a fourth conductive layer is formed according to the present disclosure.

FIG. 25 is a schematic diagram of another display substrate after a pattern of a second planarization layer is formed according to the present disclosure.

FIG. 26A and FIG. 26B are schematic diagrams of another display substrate after a pattern of a fifth conductive layer is formed according to the present disclosure.

FIG. 26C is a schematic diagram of a net-like connecting structure for an initial signal and a second power supply according to the present disclosure.

FIG. 27 is a schematic diagram of a structure of another display substrate according to an exemplary embodiment of the present disclosure.

FIG. 28A and FIG. 28B are schematic diagrams of another display substrate after a pattern of a third conductive layer is formed according to the present disclosure.

FIG. 29 is a schematic diagram of another display substrate after a pattern of a first planarization layer is formed according to the present disclosure.

FIG. 30A and FIG. 30B are schematic diagrams of another display substrate after a pattern of a fourth conductive layer is formed according to the present disclosure.

FIGS. 30C and 30D are schematic diagrams of another net-like connecting structure for an initial signal and a second power supply according to the present disclosure.

FIG. 31A and FIG. 31B are schematic diagrams of another display substrate after a pattern of an anode conductive layer is formed according to the present disclosure.

FIG. 32 is a schematic diagram of another display substrate after a pattern of a pixel definition layer is formed according to the present disclosure.

FIG. 33A and FIG. 33B are schematic diagrams of another display substrate after a pattern of an anode conductive layer is formed according to the present disclosure.

Reference signs are described as follows.

| | | |
|---|---|---|
| 11-first active layer; | 12-second active layer; | 13-third active layer; |
| 14-fourth active layer; | 15-fifth active layer; | 16-sixth active layer; |
| 17-seventh active | 18-active connection | 21-first scan signal |
| layer; | line | line; |
| 22-second scan | 23-third scan signal | 31-first initial signal |
| signal line | line; | line; |
| 32-second initial | 41-first connection | 42-second connection |
| signal line; | electrode; | electrode; |
| 43-third connection | 44-fourth connection | 45-fifth connection |
| electrode; | electrode; | electrode; |
| 46-sixth connection | 47-seventh connection | 48-eighth connection |
| electrode; | electrode; | electrode; |
| 49-ninth connection | 51-eleventh connection | 52-twelfth connection |
| electrode; | electrode | electrode; |
| 53-thirteenth connec- | 54-fourteenth connec- | 55-fifteenth connec- |
| tion electrode; | tion electrode; | tion electrode; |
| 56-light emitting signal | 61-first power supply | 62-data signal |
| connection line | line; | line; |
| 63-anode connection | 64-second power | 71-first plate; |
| electrode; | supplyl ine; | |
| 72-second plate; | 73-third plate; | 74-fourth plate; |
| 75-opening; | 76-plate connection | 81-first connection |
| | strip | line; |
| 82-second connection | 83-third connection | 90-anode; |
| line; | line; | |
| 91-first signal | 92-second signal | 93-light emitting |
| line; | line | signal line; |
| 101-base substrate; | 102-drive circuit | 103-light emitting |
| | layer; | structure layer; |
| 104-encapsulation | | |
| structure layer. | | |

### DETAILED DESCRIPTION

To make the objectives, technical solutions, and advantages of the present disclosure clearer, the embodiments of the present disclosure will be described in detail below with reference to the accompany drawings. It is to be noted that implementations may be implemented in multiple different forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the constituent elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “interconnection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the specification.

In the specification, “electrical connection” includes connection of constituent elements through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive thin film” sometimes. Similarly, an “insulation film” may be replaced with an “insulation layer” sometimes.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present disclosure, “about” refers to that a boundary is not defined so strictly and numerical values within a range of process and measurement errors are allowed.

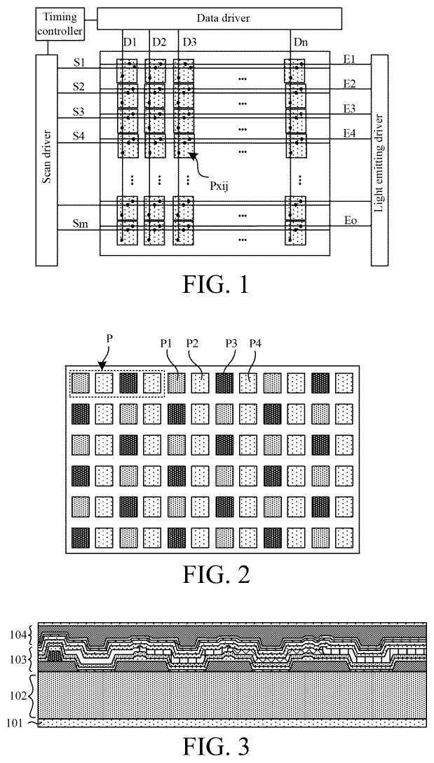

FIG. 1 is a schematic diagram of a structure of a display apparatus. As shown in FIG. 1, the display apparatus may include a timing controller, a data driver, a scan driver, a light emitting driver, and a pixel array. The timing controller is connected to the data driver, the scan driver, and the light emitting driver respectively. The data driver is connected to a plurality of data signal lines (D1 to Dn) respectively. The scan driver is connected to a plurality of scan signal lines (S1 to Sm) respectively. The light emitting driver is connected to a plurality of light emitting signal lines (E1 to Eo) respectively. The pixel array may include a plurality of sub-pixels Pxij, wherein i and j may be natural numbers. At least one sub-pixel Pxij may include a circuit unit and a light emitting unit. The circuit unit may include at least a pixel drive circuit connected to a scan signal line, a light emitting signal line and a data signal line respectively. The light emitting unit may include a light emitting device connected to the pixel drive circuit of the circuit unit. In an exemplary implementation, the timing controller may provide the data driver with a gray scale value and a control signal which are suitable for the specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate data voltages to be provided to the data signal lines DATA1, D2, D3, . . . , and Dn using the grayscale value and the control signal that are received from the timing controller. For example, the data driver may sample the gray scale value using the clock signal and apply a data voltage corresponding to the gray scale value to the data signal lines DATA1 to Dn by taking a pixel row as a unit, wherein n may be a natural number. The scan driver may generate scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines EM1, E2, E3, . . . , and Eo. For example, the light emitting driver may sequentially provide an emission signal with an off-level pulse to the light emitting signal lines EM1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number. In an exemplary implementation, the pixel array may be disposed on the display substrate.

FIG. 2 is a schematic diagram of a planar structure of a display substrate. As shown in FIG. 2, the display substrate may include a plurality of pixel units P arranged in a matrix, and at least one of the pixel units P may include a first sub-pixel P1, a second sub-pixel P2, a third sub-pixel P3, and a fourth sub-pixel P4. Each sub-pixel may include a circuit unit and a light emitting unit. The circuit unit may at least include a pixel drive circuit, the pixel drive circuit is connected to a scan signal line, a data signal line, and a light emitting signal line respectively, and is configured to receive a data voltage transmitted by the data signal line and output a corresponding current to the light emitting unit under control of the scan signal line and the light emitting signal line. The light emitting unit may include a light emitting device connected to a pixel drive circuit of a sub-pixel where the light emitting device is located, and the light emitting device is configured to emit light of a corresponding brightness in response to the current output by the pixel drive circuit of the sub-pixel where the light emitting device is located.

In an exemplary implementation, the first sub-pixels P1 may be red sub-pixels (R) emitting red light, the second sub-pixels P2 and the fourth sub-pixels P4 may be green sub-pixels (G) emitting green light, and the third sub-pixels P3 may be blue sub-pixels (B) emitting blue light. In an exemplary implementation, a sub-pixel may be in shape of a rectangle, a diamond, a pentagon, or a hexagon. The four sub-pixels may be arranged in a manner to form a diamond to form an RGBG pixel arrangement. In other exemplary implementations, the four sub-pixels may be arranged side by side horizontally, side by side vertically, or in a manner to form a square, which is not limited in the present disclosure.

In an exemplary implementation, a pixel unit may include three sub-pixels, and the three sub-pixels may be arranged side by side horizontally, side by side vertically, or in a delta-shaped arrangement, which is not limited here in the present disclosure.

FIG. 3 is a schematic diagram of a sectional structure of a display substrate, illustrating a structure of four sub-pixels in a display region. As shown in FIG. 3, on a plane perpendicular to the display substrate, the display substrate may include a drive circuit layer 102 disposed on a base substrate 101, a light emitting structure layer 103 disposed at a side of the drive circuit layer 102 away from the base substrate 101, and an encapsulation structure layer 104 disposed at a side of the light emitting structure layer 103 away from the base substrate 101. In some possible implementations, the display substrate may include another film layer, such as a touch structure layer, which is not limited here in the present disclosure.

In an exemplary implementation, the base substrate 101 may be a flexible substrate, or may be a rigid substrate. The drive circuit layer 102 may include a plurality of circuit units, each of which may at least include a pixel drive circuit composed of a plurality of transistors and a storage capacitor. The light emitting structure layer 103 may include multiple light emitting units, each light emitting unit may include a light emitting device, and the light emitting device may at least include an anode, an organic emitting layer, and a cathode. The anode is connected to a pixel drive circuit. The organic emitting layer is connected to the anode. The cathode is connected to the organic emitting layer. The organic emitting layer emits light of a corresponding color under driving of the anode and the cathode. The encapsulation layer 104 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is arranged between the first encapsulation layer and the third encapsulation layer to form a laminated structure of inorganic material/organic material/inorganic material and ensure that external moisture cannot enter the light emitting structure layer 103.

An exemplary implementation of the present disclosure provides a display substrate. In an exemplary implementation, on a plane perpendicular to the display substrate, the display substrate may include a drive structure layer disposed on a base substrate and a light emitting structure layer disposed on a side of the drive structure layer away from the base substrate. On a plane parallel to the display substrate, the drive structure layer may include a plurality of circuit units constituting a plurality of unit rows and a plurality of unit columns, and at least one of the circuit units may include a pixel drive circuit configured to output a corresponding current to a light emitting device connected to the pixel drive circuit. The light emitting structure layer may include a plurality of light emitting units. At least one of the light emitting units may include a light emitting device connected to a pixel drive circuit of the corresponding circuit unit. The light emitting device is configured to emit light of a corresponding brightness in response to a current output by the pixel drive circuit connected to the light emitting device.

In an exemplary implementation, the circuit units mentioned in the present disclosure refer to regions divided according to pixel drive circuits, and the light emitting units mentioned in the present disclosure refer to regions divided according to light emitting devices. In an exemplary implementation, a position and shape of an orthographic projection of a light emitting unit on the base substrate may correspond to a position and shape of an orthographic projection of a circuit unit on the base substrate, or the position and shape of the orthographic projection of the light emitting unit on the base substrate may not correspond to the position and shape of the orthographic projection of the circuit unit on the base substrate.

The display substrate according to the exemplary embodiment of the present disclosure may include a plurality of circuit units constituting a plurality of unit rows and a plurality of unit columns. At least one circuit unit includes a pixel drive circuit and at least one control line configured to provide a light emitting control signal to the pixel drive circuit. In at least one circuit unit, the pixel drive circuit at least includes a drive transistor, a first light emitting control transistor, and a second light emitting control transistor. A first electrode of the first light emitting control transistor is connected to a first power supply line, a second electrode of the first light emitting control transistor is connected to a first electrode of the drive transistor. A first electrode of the second light emitting control transistor is connected to a second electrode of the drive transistor. The first light emitting control transistor and the second light emitting control transistor are connected to different control lines, and the first light emitting control transistor and the second light emitting control transistor are respectively disposed at two sides of the drive transistor in a unit column direction.

In an exemplary implementation, the at least one control line includes a first signal line and a second signal line, and the first light emitting control transistor is connected to the first signal line and the second light emitting control transistor is connected to the second signal line, and the first signal line and the second signal line are respectively disposed at two sides of the drive transistor in the unit column direction.

In an exemplary implementation, the at least one control line includes a light emitting signal line, the light emitting signal line is connected to the second light emitting control transistor in the present unit row, and the light emitting signal line is connected to the first light emitting control transistor in the next unit row.

A display substrate according to an exemplary embodiment of the present disclosure is illustrated below by some examples.

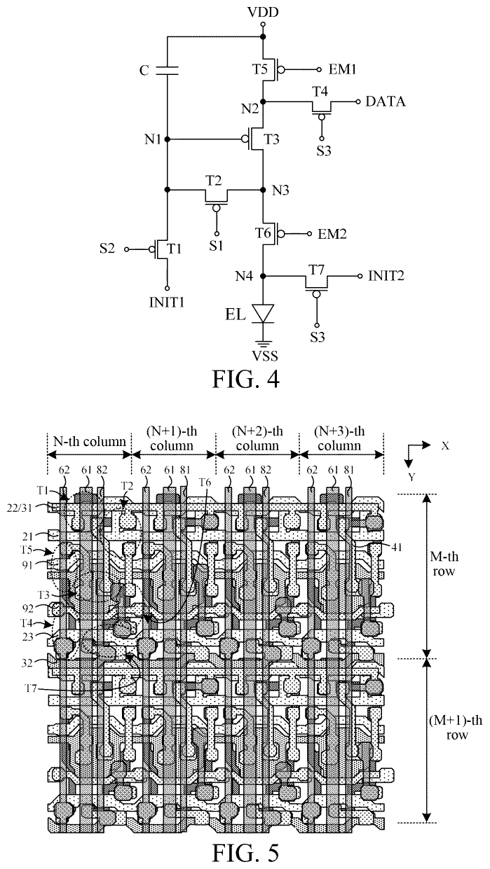

FIG. 4 is a schematic diagram of an equivalent circuit of a pixel drive circuit according to an exemplary embodiment of the present disclosure. As shown in FIG. 4, the pixel drive circuit may include seven transistors (a first transistor T1 to a seventh transistor T7) and one storage capacitor C, and the pixel drive circuit is connected to nine signal lines (a first scan signal line S1, a second scan signal line S2, a third scan signal line S3, a first signal line EM1, a second signal line EM2, a first initial signal line INIT1, a second initial signal line INIT2, a first power supply line VDD, and a data signal line DATA) respectively.

In an exemplary implementation, the pixel drive circuit may include a first node N1, a second node N2, a third node N3, and a fourth node N4. The first node N1 is connected to a second electrode of the first transistor T1, a first electrode of the second transistor T2, a gate electrode of the third transistor T3, and a second end of the storage capacitor C respectively. The second node N2 is connected to a first electrode of the third transistor T3, a second electrode of the fourth transistor T4, and a second electrode of the fifth transistor T5 respectively. The third node N3 is connected to a second electrode of the second transistor T2, a second electrode of the third transistor T3, and a first electrode of the sixth transistor T6 respectively. The fourth node N4 is connected to a second electrode of the sixth transistor T6 and a second electrode of the seventh transistor T7 respectively, and the fourth node N4 is also connected to a first electrode of a light emitting device EL.

In an exemplary implementation, a first end of the storage capacitor C is connected to the first power supply line VDD, and a second end of the storage capacitor C is connected to the first node N1.

In an exemplary implementation, a gate electrode of the first transistor T1 is connected to the second scan signal line S2, a first electrode of the first transistor T1 is connected to the first initial signal line INIT1, and the second electrode of the first transistor is connected to the first node N1. A gate electrode of the second transistor T2 is connected to the first scan signal line S1, a first electrode of the second transistor T2 is connected to the first node N1, and a second electrode of the second transistor T2 is connected to the third node N3. A gate electrode of the third transistor T3 is connected to the first node N1, a first electrode of the third transistor T3 is connected to the second node N2, and a second electrode of the third transistor T3 is connected to a third node N3. A gate electrode of the fourth transistor T4 is connected to the third scan signal line S3, a first electrode of the fourth transistor T4 is connected to the data signal line DATA, and a second electrode of the fourth transistor T4 is connected to the second node N2. A gate electrode of the fifth transistor T5 is connected to the first signal line EM1, a first electrode of the fifth transistor T5 is connected to the first power supply line VDD, and a second electrode of the fifth transistor T5 is connected to the second node N2. A gate electrode of the sixth transistor T6 is connected to the second signal line EM2, a first electrode of the sixth transistor T6 is connected to the third node N3, and a second electrode of the sixth transistor T6 is connected to the fourth node N4. A gate electrode of the seventh transistor T7 is connected to the third scan signal line S3, a first electrode of the seventh transistor T7 is connected to the second initial signal line INIT2, and a second electrode of the seventh transistor T7 is connected to the fourth node N4.

In the present disclosure, separate control of the fifth transistor T5 and the sixth transistor T6 is realized by connecting the fifth transistor T5 to the first signal line EM1 and connecting the sixth transistor T6 to the second signal line EM2, that is, the fifth transistor T5 and the sixth transistor T6 are respectively controlled by the two light emitting signal lines.

In an exemplary implementation, the light emitting device EL may be an OLED including a first electrode (anode), an organic light emitting layer, and a second electrode (cathode), which are stacked, or may be a QLED including a first electrode (anode), a quantum dot light emitting layer, and a second electrode (cathode), which are stacked. The first electrode of the light emitting device EL is connected to the fourth node N4, and a second electrode of the light emitting device EL is connected to the second power supply line VSS.

In an exemplary embodiment, a signal of the first power supply line VDD may be a high-level signal continuously provided, and a signal of the second power supply line VSS may be a low-level signal continuously provided.

In an exemplary implementation, the first transistor T1 to the seventh transistor T7 may be P-type transistors or N-type transistors. Use of a same type of transistors in a pixel drive circuit may simplify a process flow, reduce a process difficulty of a display panel, and improve a product yield. In some possible implementations, the first transistor T1 to the seventh transistor T7 may include a P-type transistor and an N-type transistor.

In an exemplary implementation, for the first transistor T1 to the seventh transistor T7, low temperature poly silicon thin film transistors may be used, or oxide thin film transistors may be used, or both a low temperature poly silicon thin film transistor and an oxide thin film transistor may be used. An active layer of a low temperature poly silicon thin film transistor is made of Low Temperature Poly silicon (LTPS for short), and an active layer of an oxide thin film transistor is made of an oxide semiconductor (Oxide). A Low temperature poly silicon thin film transistor has advantages such as a high migration rate and fast charging, and an oxide thin film transistor has advantages such as a low leakage current. The low temperature poly silicon thin film transistor and the oxide thin film transistor are integrated on one display substrate to form a Low Temperature Polycrystalline Oxide (LTPO for short) display substrate, so that advantages of both the low temperature poly silicon thin film transistor and the oxide thin film transistor may be utilized, low-frequency drive may be achieved, power consumption may be decreased, and display quality may be improved.

FIG. 5 is a schematic diagram of a structure of a display substrate according to an exemplary embodiment of the present disclosure, and illustrates a planar structure of eight circuit units (2 unit rows and 4 unit columns). As shown in FIG. 5, in a plane parallel to the display substrate, the display substrate may include a plurality of circuit units. A plurality of circuit units sequentially arranged along a first direction X are referred to as a unit row, and a plurality of circuit units sequentially arranged along a second direction Y are referred to as a unit column. The plurality of unit rows and the plurality of unit columns form an array of circuit units arranged in a matrix, and the first direction X intersects the second direction Y.

In an exemplary implementation, at least one circuit unit may include a pixel drive circuit connected to a first power supply line 61, a first signal line 91 and a second signal line 92 respectively. The first power supply line 61 is configured to provide a first power supply signal to the pixel drive circuit, the first signal line 91 is configured to provide a first light emitting control signal to the pixel drive circuit, the second signal line 92 is configured to provide a second light emitting control signal to the pixel drive circuit, and the first light emitting control signal and the second light emitting control signal are different signals.

In an exemplary implementation, the first signal line 91 and the second signal line 92 may be in a shape of a straight line or a bending line whose main body portion extends along the first direction X, and the first power supply line 61 may be in a shape of a straight line or a bending line whose main body portion extends along the second direction Y.

In the present disclosure, “A extends along a B direction” refers to that A may include a main body portion and a secondary portion connected to the main body portion, wherein the main body portion is a line, a line segment, or a strip-shaped body, the main body portion extends along the B direction, and a length of the main body portion extending along the B direction is greater than a length of the secondary portion extending along another direction. In following description, “A extends along a B direction” means “a main body portion of A extends along a B direction”.

In an exemplary implementation, the at least one pixel drive circuit may at least include a plurality of transistors, and the plurality of transistors may at least include a third transistor T3 as a drive transistor, a fifth transistor T5 as a first light emitting control transistor, and a sixth transistor T6 as a second light emitting control transistor. A gate electrode of the fifth transistor T5 is connected to the first signal line 91, a first electrode of the fifth transistor T5 is connected to the first power supply line 61, and a second electrode of the fifth transistor T5 is connected to a first electrode of the third transistor T3. A gate electrode of the sixth transistor T6 is connected to the second signal line 92, and a first electrode of the sixth transistor T6 is connected to a second electrode of the third transistor T3.

In an exemplary implementation, the fifth transistor T5 and the sixth transistor T6 may be disposed at two sides of the third transistor T3 in the first direction X (a unit row direction). For example, the fifth transistor T5 may be disposed at a side of the third transistor T3 in an opposite direction of the first direction X, and the sixth transistor T6 may be disposed at a side of the third transistor T3 in the first direction X.

In an exemplary implementation, the fifth transistor T5 and the sixth transistor T6 may be disposed at two sides of the third transistor T3 in the second direction Y (the unit column direction). For example, the fifth transistor T5 may be disposed at a side of the third transistor T3 in an opposite direction of the second direction Y, and the sixth transistor T6 may be disposed at a side of the third transistor T3 in the second direction Y.

In an exemplary implementation, the first signal line 91 and the second signal line 92 may be disposed at two sides of the third transistor T3 in the second direction Y (the unit column direction). For example, the first signal line 91 may be disposed at a side of the third transistor T3 in an opposite direction of the second direction Y, and the second signal line 92 may be disposed at a side of the third transistor T3 in the second direction Y.

In an exemplary implementation, the display substrate may include a plurality of conductive layers in a direction perpendicular to the display substrate, and the first signal line 91 and the second signal line 92 may be disposed in different conductive layers.

In an exemplary implementation, the sixth transistor T6 may at least include a sixth gate electrode, the sixth gate electrode may serve as the second gate of the present disclosure, the sixth gate electrode and the second signal line 92 may be disposed in different conductive layers, and the second signal line 92 may be connected to the sixth gate electrode through a via.

In an exemplary implementation, the sixth gate electrode and the first signal line 91 may be disposed in a same conductive layer.

In an exemplary implementation, the pixel drive circuit may further include a second transistor T2 as a compensation transistor. A gate electrode of the second transistor T2 is connected to the first scan signal line 21, a first electrode of the second transistor T2 is connected to a gate electrode of the third transistor T3 via the first connection electrode 41, and a second electrode of the second transistor T2 is connected to a second electrode of the third transistor T3 and a first electrode of the sixth transistor T6, respectively.

In an exemplary implementation, an orthographic projection of the first connection electrode 41 on the plane of the display substrate is at least partially overlapped with an orthographic projection of the first signal line 91 on the plane of the display substrate, and the orthographic projection of the first connection electrode 41 on the plane of the display substrate is at least partially overlapped with an orthographic projection of the first scan signal line 21 on the plane of the display substrate, that is, the first connection electrode 41 is overlapped with the first signal line 91 and the first scan signal line 21 at the same time.

In an exemplary implementation, the pixel drive circuit may further include a first transistor T1 as a first initialization transistor. A gate electrode of the first transistor T1 is connected to a second scan signal line 22, a first electrode of the first transistor T1 is connected to a first initial signal line 31, and a second electrode of the first transistor T1 is connected to a gate electrode of the third transistor T3 through the first connection electrode 41. The first initial signal line 31 is configured to provide a first initial signal to the pixel drive circuit, and the first initial signal line 31 may be in a shape of a straight line or a bending line extending along the first direction X.

In an exemplary implementation, at least one circuit unit may further include a first connection line 81 extending along the second direction Y, and the first connection line 81 is connected to the first initial signal line 31 to form a net-like connecting structure for transmitting the first initial signal on the display substrate.

In an exemplary implementation, the pixel drive circuit may further include a seventh transistor T7 as a second initialization transistor. A gate electrode of the seventh transistor T7 is connected to a third scan signal line 23, a first electrode of the seventh transistor T7 is connected to a second initial signal line 32, and a second electrode of the seventh transistor T7 is connected to a second electrode of the sixth transistor T6. The second initial signal line 32 is configured to provide a second initial signal to the pixel drive circuit, and the second initial signal line 32 may be in a shape of a straight line or a bending line extending along the first direction X.

In an exemplary implementation, at least one circuit unit may further include a second connection line 82 extending along the second direction Y, and the second connection line 82 is connected to the second initial signal line 32 to form a net-like connecting structure for transmitting the second initial signal on the display substrate.

In an exemplary implementation, the first initial signal line 31 and the second initial signal line 32 may be disposed in each unit row, and the first connection lines 81 and the second connection lines 82 may be alternately disposed in a plurality of unit columns.

In an exemplary implementation, the pixel drive circuit may further include a fourth transistor T4 as a data writing transistor. A gate electrode of the fourth transistor T4 is connected to the third scan signal line 23, a first electrode of the fourth transistor T4 is connected to a data signal line 62, and a second electrode of the fourth transistor T4 is connected to the first electrode of the third transistor T3, and the second transistor T2 and the fourth transistor T4 may be disposed at two sides of the third transistor T3 in the second direction Y (the unit column direction). For example, the second transistor T2 may be disposed at a side of the third transistor T3 in an opposite direction of the second direction Y, and the fourth transistor T4 may be disposed at a side of the third transistor T3 in the second direction Y.

In an exemplary implementation, in a plane perpendicular to the display substrate, the display substrate includes a semiconductor layer, a first conductive layer, a second conductive layer, a third conductive layer, a fourth conductive layer and that are sequentially disposed on the base substrate. The semiconductor layer may include active layers of a plurality of transistors, the first conductive layer may at least include a first signal line 91, a plurality of scan signal lines, and gate electrodes of the plurality of transistors, the second conductive layer may at least include a second initial signal line 32, the third conductive layer may at least include a first initial signal line 31, a second signal line 92, and a plurality of connection electrodes, and the fourth conductive layer may at least include a first power supply line 61, a first connection line 81, and a second connection line 82.

In an exemplary implementations, the display substrate may further include a first insulation layer, a second insulation layer, a third insulation layer, a fourth insulation layer, and a first planarization layer. The first insulation layer may be disposed between the base substrate and the semiconductor layer, the second insulation layer may be disposed between the semiconductor layer and the first conductive layer, the third insulation layer may be disposed between the first conductive layer and the second conductive layer, the fourth insulation layer may be disposed between the second conductive layer and the third conductive layer, and the first planarization layer may be disposed between the third conductive layer and the fourth conductive layer.

Exemplary description is made below through a manufacturing process of a display substrate. A “patterning process” mentioned in the present disclosure includes a treatment such as deposition of a film layer, photoresist coating on a film layer, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are arranged in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In an exemplary embodiment, taking eight circuit units (two unit rows and four unit columns) as an example, a manufacturing process for the display substrate of the present embodiment may include the following operations.

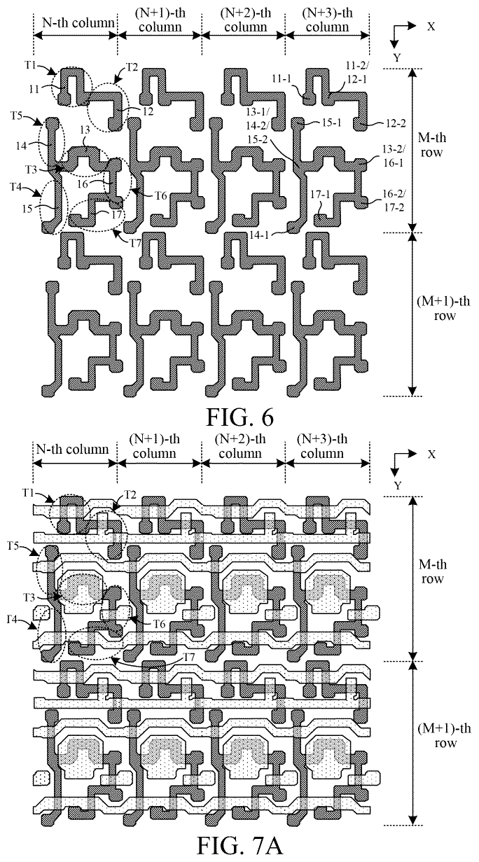

(11) A pattern of a semiconductor layer is formed. In an exemplary implementation, forming the pattern of the semiconductor layer may include: depositing a first insulation thin film and a semiconductor thin film sequentially on a base substrate, and the semiconductor thin film is patterned through a patterning process to form a first insulation layer that covers the base substrate and the semiconductor layer disposed on the first insulation layer, as shown in FIG. 6.

In an exemplary implementation, the semiconductor layer may include a first active layer 11 of the first transistor T1 to a seventh active layer 17 of the seventh transistor T7, and the first active layer 11 and the second active layer 12 are of an interconnected integral structure, and the third active layer 13 to the seventh active layer 17 are of an interconnected integral structure.

In an exemplary implementation, in the first direction X, the fourth active layer 14 and the fifth active layer 15 in an N-th unit column may be located on a side of the third active layer 13 of the present circuit unit away from an (N+1)-th unit column, and the sixth active layer 16 may be located on a side of the third active layer 13 of the present circuit unit close to the (N+1)-th unit column, that is, the fifth active layer 15 and the sixth active layer 16 are respectively located on two sides of the third active layer 13 in the first direction X.

In an exemplary implementation, in the second direction Y, the first active layer 11, the second active layer 12, and the fifth active layer 15 in an M-th unit row may be located at a side of the third active layer 13 of the present circuit unit away from an (M+1)-th unit row, and the fourth active layer 14, the sixth active layer 16, and the seventh active layer 17 may be located at a side of the third active layer 13 of the present circuit unit close to the (M+1)-th unit row, that is, the fifth active layer 15 and the sixth active layer 16 are respectively located at two sides of the second direction Y of the third active layer 13.

The present disclosure facilitates realization of separate control of the fifth transistor T5 and the sixth transistor T6 by providing the fifth transistor T5 and the sixth transistor T6 at two sides of the third transistor T3 in the first direction X and in the second direction Y.

In an exemplary implementation, the first active layer 11 may be in an “n” shape, the second active layer 12 and the seventh active layer 17 may be in an “L” shape, the third active layer 13 may be in an “Q” shape, and the fourth active layer 14, the fifth active layer 15, and the sixth active layer 16 may be in an “I” shape.

In an exemplary implementation, an active layer of each transistor may include a first region, a second region, and a channel region located between the first region and the second region. In an exemplary implementation, a second region 11-2 of the first active layer may serve as a first region 12-1 of the second active layer, that is, the second region 11-2 of the first active layer and the first region 12-1 of the second active layer are connected to each other. A first region 13-1 of the third active layer may simultaneously serve as a second region 14-2 of the fourth active layer and a second region 15-2 of the fifth active layer, that is, the first region 13-1 of the third active layer, the second region 14-2 of the fourth active layer and the second region 15-2 of the fifth active layer are connected to each other. A second region 13-2 of the third active layer may serve as a first region 16-1 of the sixth active layer, that is, the second region 13-2 of the third active layer and the first region 16-1 of the sixth active layer are connected to each other. A second region 16-2 of the sixth active layer may serve as a second region 17-2 of the seventh active layer, that is, the second region 16-2 of the sixth active layer and the second region 17-2 of the seventh active layer are connected to each other. A first region 11-1 of the first active layer 11, a second region 12-2 of the second active layer, a first region 14-1 of the fourth active layer, a first region 15-1 of the fifth active layer, and a first region 17-1 of the seventh active layer may be separately provided.

In an exemplary implementation, the first semiconductor layer may be made of polysilicon (p-Si), i.e., the first to seventh transistors are LTPS transistors. In an exemplary implementation, the patterning the first semiconductor thin film through the patterning process may include: forming an amorphous silicon (a-si) thin film on the first insulation thin film, dehydrogenating the amorphous silicon thin film, and crystallizing the dehydrogenated amorphous silicon thin film to form a poly silicon thin film. Subsequently, the poly silicon thin film is patterned to form the pattern of the first semiconductor layer.

(12) A pattern of a first conductive layer is formed. In an exemplary implementation, forming the pattern of the first conductive layer may include: depositing sequentially a second insulation thin film and a first conductive thin film on the base substrate on which the aforementioned patterns are formed, and patterning the first conductive thin film through a patterning process to form a second insulation layer that covers a pattern of the semiconductor layer and form the pattern of the first conductive layer provided on the second insulation layer, as shown in FIG. 7A and FIG. 7B, and FIG. 7B is a planar schematic diagram of the first conductive layer in FIG. 7A. In an exemplary implementation, the first conductive layer may be referred to as a first gate metal (GATE1) layer.

In an exemplary implementation, the pattern of the first conductive layer of each circuit unit at least includes a first scan signal line 21, a second scan signal line 22, a third scan signal line 23, a sixth gate electrode 26, a first plate 71 of a storage capacitor, and a first signal line 91.

In an exemplary embodiment, the first plate 71 may be in a shape of a rectangle, and a chamfer or groove may be provided at a corner of the rectangle. An orthographic projection of the first plate 71 on the base substrate is at least partially overlapped with an orthographic projection of the third active layer of the third transistor T3 on the base substrate. In an exemplary implementation, the first plate 71 may serve as one plate of the storage capacitor and a gate electrode of the third transistor T3 simultaneously.

In an exemplary implementation, the first scan signal line 21 may be in a shape of a straight line or a bending line whose main body portion extends along the first direction X. The first scan signal line 21 may be located at a side of the first plate 71 in an opposite direction of the second direction Y, a gate block 21-1 is connected to a side of the first scan signal line 21 away from the first plate 71, and a region where the first scan signal line 21 and the gate block 21-1 overlap with the second active layer may serve as a gate electrode of the second transistor T2 with a double-gate structure.

In an exemplary embodiment, the second scan signal line 22 may be in a shape of a straight line or a bending line whose main body portion extends along the first direction X. The second scan signal line 22 may be located at a side of the first scan signal line 21 away from the first plate 71, and a region where the second scan signal line 22 overlaps with the first active layer may serve as a gate electrode of the first transistor T1 with a double gate structure.

In an exemplary implementation, the third scan signal line 23 may be in a shape of a straight line or a bending line whose main body portion extends along the first direction X. The third scan signal line 23 may be located at a side of the first plate 71 in an opposite direction of the second direction Y, a region where the third scan signal line 23 overlaps with the fourth active layer may serve as a gate electrode of the fourth transistor T4, and a region where the third scan signal line 23 overlaps with the seventh active layer may serve as a gate electrode of the seventh transistor T7, that is, the fourth transistor T4 and the seventh transistor T7 of the present disclosure are controlled to be turned on and off by a same scan signal line.

In an exemplary implementation, the first signal line 91 may be in a shape of a straight line or a bending line whose main body portion extends along the first direction X. The first signal line 91 may be located between the first scan signal line 21 and the first plate 71, and a region where the first signal line 91 overlaps with the fifth active layer may serve as a gate electrode of the fifth transistor T5.

In an exemplary implementation, the sixth gate electrode 26 may be in a shape of a strip extending along the first direction X. The sixth gate electrode 26 may be located between the third scan signal line 23 and the first plate 71, and a region where the sixth gate electrode 26 overlaps with the sixth active layer may serve as a gate electrode of the sixth transistor T6. In an exemplary implementation, the sixth gate electrode 26 is configured to be connected to the second signal line to be formed subsequently.

In an exemplary implementation, the first scan signal line 21, the second scan signal line 22, the third scan signal line 23, and the first signal line 91 each include a region which is overlapped with the first semiconductor layer and a region which is not overlapped with the first semiconductor layer. A width of at least one signal line in the region which is overlapped with the first semiconductor layer may be greater than a width of at least one signal line in the region which is not overlapped with the first semiconductor layer, and the width can be a size in the second direction Y.

In an exemplary implementation, after the pattern of the first conductive layer is formed, a conductive processing may be performed on the semiconductor layer by using the first conductive layer as a shield. The semiconductor layer in a region shielded by the first conductive layer forms channel regions of the first transistor T1 to the seventh transistor T7, and the semiconductor layer in a region not shielded by the first conductive layer is made to be conductive, that is, first regions and second regions of the first active layer to the seventh active layer are all made to be conductive.

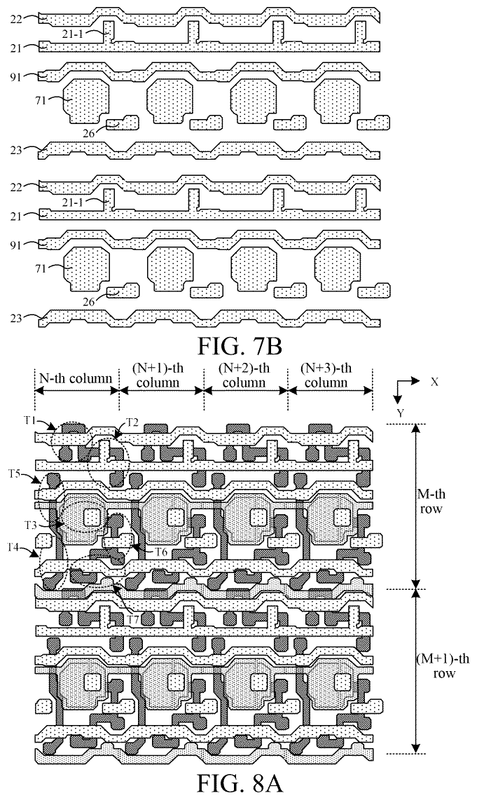

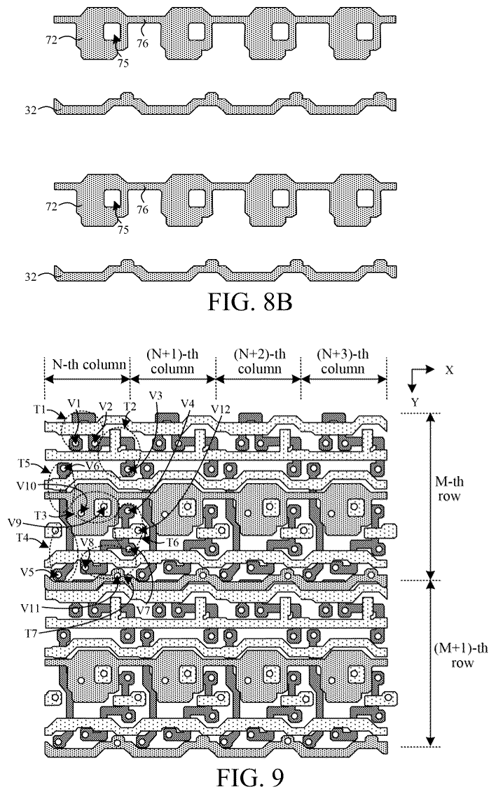

(13) A pattern of a second conductive layer is formed. In an exemplary implementation, forming the pattern of the second conductive layer may include: depositing sequentially a third insulation thin film and a second conductive thin film on the base substrate on which the aforementioned patterns are formed, and the second conductive thin film is patterned through a patterning process to form a third insulation layer that covers the first conductive layer and the pattern of the second conductive layer provided on the third insulation layer, as shown in FIG. 8A and FIG. 8B. FIG. 8B is a planar schematic diagram of the second conductive layer in FIG. 8A. In an exemplary implementation, the second conductive layer may be referred to as a second gate metal (GATE2) layer.

In an exemplary implementation, the pattern of the second conductive layer of each circuit unit may at least include a second initial signal line 32 and a second plate 72 of the storage capacitor.

In an exemplary embodiment, a profile of second plate 72 may be in a shape of a rectangle, a chamfer may be provided at a corner of the rectangle, an orthographic projection of the second plate 72 on the base substrate is at least overlapped with an orthographic projection of the first plate 71 on the base substrate, the second plate 72 may serve as another plate of the storage capacitor, and the first plate 71 and the second plate 72 form the storage capacitor of the pixel drive circuit.

In an exemplary implementation, the second plate 72 is provided with an opening 75. The opening 75 may have a rectangular shape and may be located in the middle of the second plate 72, so that the second plate 72 is formed in an annular structure. The opening 75 exposes the third insulation layer covering the first plate 71, and an orthographic projection of the first plate 71 on the base substrate contains an orthographic projection of the opening 75 on the base substrate. In an exemplary implementation, the opening 75 is configured to accommodate a ninth via to be formed subsequently, and the ninth via is within the opening 75 and exposes the first plate 71, so that a first connection electrode to be formed subsequently is connected to the first plate 71.

In an exemplary implementation, the second conductive layer of each circuit unit may further include a plate connection strip 76. The plate connection strip 76 may be in a shape of a strip extending along the first direction X, and the plate connection strip 76 may be provided on a side of the second plate 72 in the first direction X or on a side of the second plate 72 in an opposite direction of the first direction X. A first end of the plate connection strip 76 is connected to the second plate 72 in the present circuit unit, and a second end of the plate connection strip 76 is connected to the second plate 72 in a circuit unit adjacent in the first direction X, so that the second plates 72 in adjacent circuit units in one unit row are interconnected to be in an integral structure. Since the second plate 72 in each circuit unit is connected to a first power supply line to be formed subsequently, by forming an integral structure in which the second plates 72 of adjacent circuit units are connected to each other, the second plates of the integral structure can also be used as a power supply signal line, so that a plurality of second plates in a unit row can be ensured to have a same potential, which is beneficial for improving uniformity of the display substrate, avoiding poor display of the display substrate and ensuring a display effect of the display substrate.

In an exemplary implementation, the second initial signal line 32 may be in a shape of a straight line or a bending line whose main body portion extends along the first direction X, and the second initial signal line 32 may be located at a side of the third scan signal line 23 away from the second plate 72. In an exemplary implementation, the second initial signal line 32 is configured to be connected to a first region of the seventh active layer by a sixth connection electrode to be formed subsequently.

(14) A pattern of a fourth insulation layer is formed. In an exemplary implementation, forming the pattern of the fourth insulation layer may include: depositing a fourth insulating thin film on the base substrate on which the aforementioned patterns are formed, and patterning the fourth insulating thin film by a patterning process, to form a fourth insulation layer covering the second conductive layer, wherein a plurality of vias are provided on the fourth insulation layer, as shown in FIG. 9.

In an exemplary implementation, multiple vias in each circuit unit may at least include: a first via V1, a second via V2, a third via V3, a fourth via V4, a fifth via V5, a sixth via V6, a seventh via V7, an eighth via V8, a ninth via V9, a tenth via V10, an eleventh via V11, and a twelfth via V12.

In an exemplary implementation, an orthographic projection of the first via V1 on the base substrate is within a range of an orthographic projection of the first region of the first active layer on the base substrate, the fourth insulation layer, the third insulation layer, and the second insulation layer within the first via V1 are etched away to expose a surface of the first region of the first active layer, and the first via V1 is configured such that an initial connection block to be formed subsequently is connected to the first region of the first active layer through the first via V1.

In an exemplary implementation, an orthographic projection of the second via V2 on the base substrate is within a range of an orthographic projection of the second region of the first active layer (also the first region of the second active layer) on the base substrate, the fourth insulation layer, the third insulation layer, and the second insulation layer within the second via V2 are etched away to expose a surface of the second region of the first active layer, and the second via V2 is configured such that the first connection electrode to be formed subsequently is connected to the second region of the first active layer (also the first region of the second active layer) through the second via V2.

In an exemplary implementation, an orthographic projection of the third via V3 on the base substrate is within a range of an orthographic projection of the second region of the second active layer on the base substrate, the fourth insulation layer, the third insulation layer, and the second insulation layer within the third via V3 are etched away to expose a surface of the second region of the second active layer, and the third via V3 is configured such that a fifth connection electrode to be formed subsequently is connected to the second region of the second active layer through the third via V3.

In an exemplary implementation, an orthographic projection of the fourth via V4 on the base substrate is within a range of an orthographic projection of the second region of the third active layer (also the first region of the sixth active layer) on the base substrate, the fourth insulation layer, the third insulation layer, and the second insulation layer within the fourth via V4 are etched away to expose a surface of the second region of the third active layer, and the fourth via V4 is configured such that the fifth connection electrode to be formed subsequently is connected to the second region of the third active layer (also the first region of the sixth active layer) through the fourth via V4.

In an exemplary implementation, an orthographic projection of the fifth via V5 on the base substrate is within a range of an orthographic projection of the first region of the fourth active layer on the base substrate, the fourth insulation layer, the third insulation layer, and the second insulation layer within the fifth via V5 are etched away to expose a surface of the first region of the fourth active layer, and the fifth via V5 is configured such that a third connection electrode to be formed subsequently is connected to the first region of the fourth active layer through the fifth via V5.

In an exemplary implementation, an orthographic projection of the sixth via V6 on the base substrate is within a range of an orthographic projection of the first region of the fifth active layer on the base substrate, the fourth insulation layer, the third insulation layer, and the second insulation layer within the sixth via V6 are etched away to expose a surface of the first region of the fifth active layer, and the sixth via V6 is configured such that a second connection electrode to be formed subsequently is connected to the first region of the fifth active layer through the sixth via V6.

In an exemplary implementation, an orthographic projection of the seventh via V7 on the base substrate is within a range of an orthographic projection of the second region of the sixth active layer (also the second region of the seventh active layer) on the base substrate, the fourth insulation layer, the third insulation layer, and the second insulation layer within the seventh via V7 are etched away to expose a surface of the second region of the sixth active layer, and the seventh via V7 is configured such that a fourth connection electrode to be formed subsequently is connected to the second region of the sixth active layer (also the second region of the seventh active layer) through the seventh via V7.

In an exemplary implementation, an orthographic projection of the eighth via V8 on the base substrate is within a range of an orthographic projection of the first region of the seventh active layer on the base substrate, the fourth insulation layer, the third insulation layer, and the second insulation layer within the eighth via V8 are etched away to expose a surface of the first region of the seventh active layer, and the eighth via V8 is configured such that the sixth connection electrode to be formed subsequently is connected to the first region of the seventh active layer through the eighth via V8.

In an exemplary implementation, an orthographic projection of the ninth via V9 on the base substrate is within a range of an orthographic projection of the opening 75 on the base substrate, the fourth insulation layer and the third insulation layer within the ninth via V9 are etched away to expose a surface of the first plate 71, and the ninth via V9 is configured such that the first connection electrode to be formed subsequently is connected to the first plate 71 through the ninth via V9.

In an exemplary implementation, an orthographic projection of the tenth via V10 on the base substrate is within a range of an orthographic projection of the second plate 72 on the base substrate, the fourth insulation layer within the tenth via V10 is etched away to expose a surface of the second plate 72, and the tenth via V10 is configured such that the second connection electrode to be formed subsequently is connected to the second plate 72 through the tenth via V10.

In an exemplary implementation, an orthographic projection of the eleventh via V11 on the base substrate is within a range of an orthographic projection of the second initial signal line 32 on the base substrate, the fourth insulation layer within the eleventh via V11 is etched away to expose a surface of the second initial signal line 32, and the eleventh via V11 is configured such that the sixth connection electrode to be formed subsequently is connected to the second initial signal line 32 through the eleventh via V11.

In an exemplary implementation, an orthographic projection of the twelfth via V12 on the base substrate is within a range of an orthographic projection of the sixth gate electrode 26 on the base substrate, the fourth insulation layer and the third insulation layer within the twelfth via V12 are etched away to expose a surface of the sixth gate electrode 26, and the twelfth via V12 is configured such that the second signal line to be formed subsequently is connected to the sixth gate electrode 26 through the twelfth via V12.

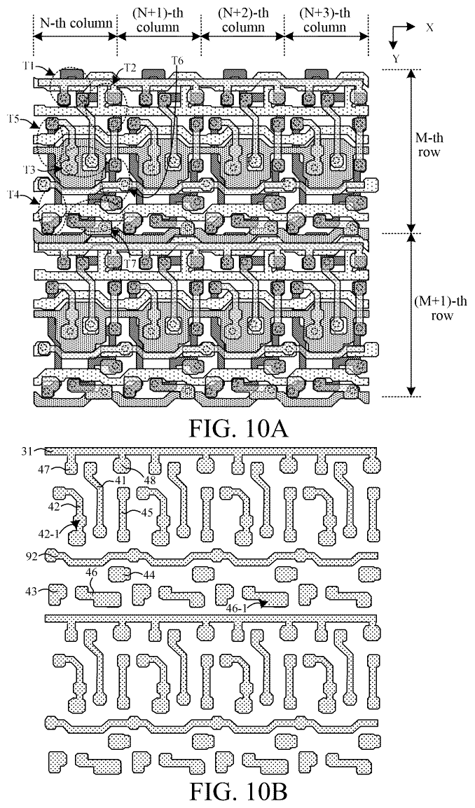

(15) A pattern of a third conductive layer is formed. In an exemplary implementation, forming the third conductive layer may include: depositing a third conductive thin film on the base substrate on which the aforementioned patterns are formed, and patterning the third conductive thin film by a patterning process to form the third conductive layer provided on the fourth insulation layer, as shown in FIG. 10A and FIG. 10B, and FIG. 10B is a planar schematic diagram of the third conductive layer in FIG. 10A. In an exemplary implementation, the third conductive layer may be referred to as a first source-drain metal (SD1) layer.

In an exemplary implementation, the third conductive layer of each circuit unit may at least include a first initial signal line 31, a first connection electrode 41, a second connection electrode 42, a third connection electrode 43, a fourth connection electrode 44, a fifth connection electrode 45, a sixth connection electrode 46, a seventh connection electrode 47, an eighth connection electrode 48, and a second signal line 92.

In an exemplary implementation, the first initial signal line 31 may be in a shape of a straight line or a bending line extending along the first direction X. The first initial signal line 31 may be located at a side of the first scan signal line 21 away from the second plate 72, an orthographic projection of the first initial signal line 31 on the base substrate is at least partially overlapped with an orthographic projection of the second scan signal line 22 on the base substrate, and the first initial signal line 31 with a constant voltage may play a shielding role to reduce influence of the second scan signal line 22 on the pixel drive circuit.

In an exemplary implementation, the second signal line 92 may be in a shape of a straight line or a bending line extending along the first direction X. The second signal line 92 may be located between the third scan signal line 23 and the second plate 72, and the second signal line 92 may be connected to the sixth gate electrode 26 of each circuit unit through the twelfth via V12 of each circuit unit, so that the second signal line 92 may control turn-on and turn-off of the sixth transistor T6.

In an exemplary implementation, the first connection electrode 41 may be in a shape of a strip extending along the second direction Y, a first end of the first connection electrode 41 is connected to the second region of the first active layer (also the first region of the second active layer) through the second via V2, and a second end of the first connection electrode 41 is connected to the first plate 71 through the ninth via V9. In an exemplary implementation, since the first plate 71 simultaneously serves as a gate electrode of the third transistor T3, the first connection electrode 51 enables the second electrode of the first transistor T1, the first electrode of the second transistor T2, the gate electrode of the third transistor T3 and the first plate 71 to have a same potential and form the first node N1 of the pixel drive circuit.

In an exemplary implementation, an orthographic projection of the first connection electrode 41 on the base substrate is at least partially overlapped with an orthographic projection of the first scan signal line 21 on the base substrate, and the orthographic projection of the first connection electrode 41 on the base substrate is at least partially overlapped with an orthographic projection of the first signal line 91 on the base substrate, that is, the first connection electrode 41 simultaneously is overlapped with both the first scan signal line 21 and the first signal line 91. Compared with an existing structure in which the first node N1 is overlapped with one signal line, in the present disclosure, by providing the first node N1 of the pixel drive circuit to be overlapped with the first scan signal line 21 and the first signal line 91, respectively, coupling influence to which the first node N1 node is subjected can be complemented by jumping of the two signal lines.

In an exemplary implementation, the second connection electrode 42 may be in a shape of a strip extending along the second direction Y, a first end of the second connection electrode 42 is connected to the first region of the fifth active layer through the sixth via V6, and a second end of the second connection electrode 42 is connected to the second plate 72 through the tenth via V10. In an exemplary implementation, the second connection electrode 42 realizes that the first electrode of the fifth transistor T5 and the second plate 72 of the storage capacitor in each circuit unit have a same potential.

In an exemplary implementation, a first power supply connection block 42-1 may be provided between the first end and the second end of the second connection electrode 42, the first power supply connection block 42-1 may be in a shape of a block (such as a rectangle), an orthographic projection of the first power supply connection block 42-1 on the base substrate may be within a range of an orthographic projection of the second plate 72 on the base substrate, and the first power supply connection block 42-1 is configured to be connected to the first power supply line to be formed subsequently.

In an exemplary implementation, the third connection electrode 43 may be in a shape of a block (such as a rectangle) and the third connection electrode 43 is connected to the first region of the fourth active layer through the fifth via V5. In an exemplary implementation, the third connection electrode 43 may serve as the first electrode of the fourth transistor T4, and the third connection electrode 43 is configured to be connected to a data signal line to be formed subsequently.

In an exemplary implementation, the fourth connection electrode 44 may be in a shape of a block (such as a rectangle), and the fourth connection electrode 44 is connected to the second region of the sixth active layer (also the second region of the seventh active layer) through the seventh via V7. In an exemplary implementation, the fourth connection electrode 44 may serve as the second electrode of the sixth transistor T6 and the second electrode of the seventh transistor T7 simultaneously, and the fourth connection electrode 44 is configured to be connected to an anode connection electrode to be formed subsequently.

In an exemplary implementation, the fifth connection electrode 45 may be in a shape of a strip extending along the second direction Y, a first end of the fifth connection electrode 45 is connected to the second region of the second active layer through the third via V3, and a second end of the fifth connection electrode 45 is connected to the first region of the sixth active layer through the fourth via V4. In an exemplary implementation, since the first region of the sixth active layer may serve as the second region of the third active layer, the fifth connection electrode 45 causes a second electrode of the second transistor T2, a second electrode of the third transistor T3, and a first electrode of the sixth transistor T6 to have a same potential to form the third node N3 of the pixel drive circuit. The second active layer may serve as the compensation active layer of the present disclosure, the sixth active layer may serve as the second light emitting control active layer of the present disclosure, the second active layer and the sixth active layer are disposed in the semiconductor layer, and the fifth connection electrode is disposed in the third conductive layer, and thus the sixth active layer and the fifth connection electrode are disposed in different film layers.

In an exemplary implementation, the sixth connection electrode 46 may be in a shape of a strip extending along the first direction X, a first end of the sixth connection electrode 46 is connected to the first region of the seventh active layer through the eighth via V8, and a second end of the sixth connection electrode 46 is connected to the second initial signal line 32 through the eleventh via V11, so that the second initial signal line 32 can write the second initial signal to a first electrode of the seventh transistor T7.

In an exemplary implementation, the sixth connection electrode 46 in some of circuit units may be connected to an initial connection block 46-1, which may be in a shape of a block (such as a rectangle), and the initial connection block 46-1 is configured to be connected to the second connection line to be formed subsequently. For example, the initial connection block 46-1 may be provided in the circuit units in an N-th unit column and an (N+2)-th unit column.

In an exemplary implementation, the seventh connection electrode 47 may be in a shape of a block (such as a rectangle), the seventh connection electrode 47 may be disposed at a side of the first initial signal line 31 close to the first scan signal line 21, a first end of the seventh connection electrode 47 is connected to the first initial signal line 31, and a second end of the seventh connection electrode 47 is connected to the first region of the first active layer through the first via V1, so that the first initial signal line 31 can write the first initial signal to the first electrode of the first transistor T1.

In an exemplary implementation, the first initial signal line 31 and the seventh connection electrode 47 may be of an interconnected integral structure.

In an exemplary implementation, the eighth connection electrode 48 may be in a shape of a block (such as a rectangle), the eighth connection electrode 48 may be disposed at a side of the first initial signal line 31 close to the first scan signal line 21, a first end of the eighth connection electrode 48 is connected to the first initial signal line 31, a second end of the eighth connection electrode 48 extends in a direction of the first scan signal line 21. The eighth connection electrode 48 may serve as a node shielding electrode, an orthographic projection of the eighth connection electrode 48 on the base substrate is at least partially overlapped with an orthographic projection of the second active layer between two gate electrodes of the second transistor T2 on the base substrate, and the eighth connection electrode 48 with a constant voltage can play a shielding role to reduce influence of signals in the pixel drive circuit on the node between the two gate electrodes of the second transistor T2, and to ensure the electrical performance of the second transistor T2.

In an exemplary implementation, the first initial signal line 31 and the eighth connection electrode 48 may be an integral structure connected to each other.

In an exemplary implementation, the eighth connection electrode 48 in the circuit units of an (N+1)-th unit column and an (N+3)-th unit column is further configured to be connected to the first connection line to be formed subsequently, while the eighth connection electrode 48 in the circuit units of the N-th unit column and an (N+2)-th unit column serves as a dummy-pad and is not connected to the fourth conductive layer to be formed subsequently.

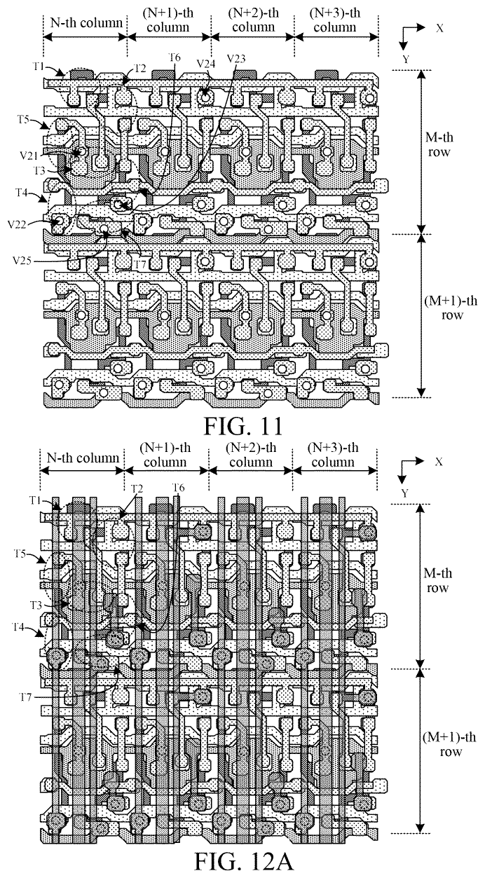

(16) A pattern of a first planarization layer is formed. In an exemplary implementation, forming the pattern of the first planarization layer may include coating a first planarization thin film on the base substrate on which the above-mentioned patterns are formed, patterning the first planarization thin film through a patterning process, to form a first planarization layer covering the third conductive layer, wherein the first planarization layer is provided with a plurality of vias, as shown in FIG. 11.

In an exemplary embodiment, the plurality of vias in each circuit unit at least includes a twenty-first via V21, a twenty-second via V22, and a twenty-third via V23.

In an exemplary implementation, an orthographic projection of the twenty-first via V21 on the base substrate is within a range of an orthographic projection of the first power supply connection block 42-1 on the base substrate, the first planarization layer within the twenty-first via V21 is removed to expose a surface of the first power supply connection block 42-1, and the twenty-first via V21 is configured such that the first power supply line to be formed subsequently is connected to the first power supply connection block 42-1 through the twenty-first via V21.

In an exemplary implementation, the twenty-first via V21 may be referred to as a power supply via, and an orthographic projection of the twenty-first via V21 on the base substrate may be within a range of an orthographic projection of the second plate 72 on the base substrate.

In an exemplary implementation, an orthographic projection of the twenty-second via 22 on the base substrate is within a range of an orthographic projection of the third connection electrode 43 on the base substrate, the first planarization layer within the twenty-second via V22 is removed to expose a surface of the third connection electrode 43, and the twenty-second via V22 is configured such that a data signal line to be formed subsequently is connected to the third connection electrode 43 through the twenty-second via V22.

In an exemplary implementation, an orthographic projection of the twenty-third via V23 on the base substrate is within a range of an orthographic projection of the fourth connection electrode 44 on the base substrate, the first planarization layer within the twenty-third via V23 is removed to expose a surface of the fourth connection electrode 44, and the twenty-third via V23 is configured such that an anode connection electrode to be formed subsequently is connected to the fourth connection electrode 44 through the twenty-third via V23.

In an exemplary implementation, a twenty-fourth via V24 and a twenty-fifth via V25 may be further provided on the first planarization layer.

In an exemplary implementation, an orthographic projection of the twenty-fourth via V24 on the base substrate is within a range of an orthographic projection of the eighth connection electrode 48 on the base substrate, the first planarization layer within the twenty-fourth via V24 is removed to expose a surface of the eighth connection electrode 48, and the twenty-fourth via V24 is configured such that the first connection line to be formed subsequently is connected to the eighth connection electrode 48 through the twenty-fourth via V24. In an exemplary implementation, the twenty-fourth via V24 may be disposed in the circuit units of the (N+1)-th unit column and the (N+3)-th unit column.

In an exemplary implementation, an orthographic projection of the twenty-fifth via V25 on the base substrate is within a range of an orthographic projection of the initial connection block 46-1 on the base substrate, the first planarization layer within the twenty-fifth via V25 is removed to expose a surface of the initial connection block 46-1, and the twenty-fifth via V25 is configured such that the second connection line to be formed subsequently is connected to the initial connection block 46-1 through the twenty-fifth via V25. In an exemplary implementation, the twenty-fifth via V25 may be disposed in the circuit units of the N-th unit column and the (N+2)-th unit column.

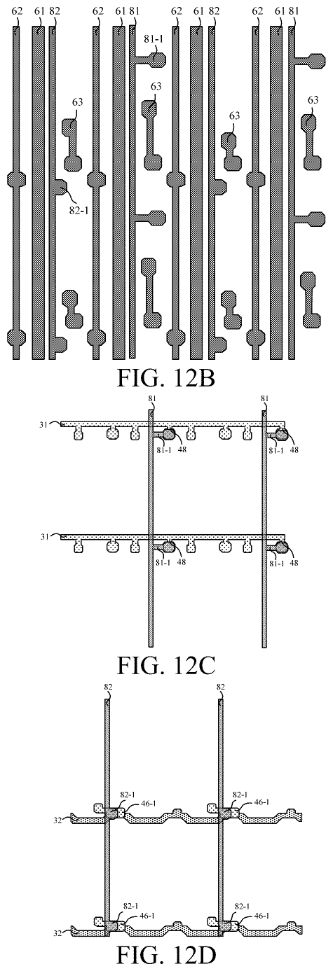

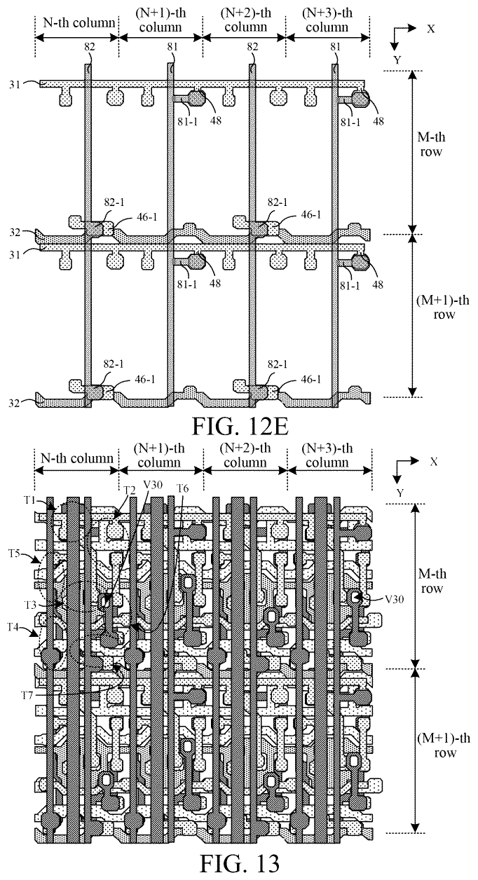

(17) A pattern of a fourth conductive layer is formed. In an exemplary implementation, forming the pattern of the fourth conductive layer may include: depositing a fourth conductive thin film on the base substrate on which the aforementioned patterns are formed, and patterning the fourth conductive thin film by a patterning process to form the fourth conductive layer provided on the first planarization layer, as shown in FIG. 12A and FIG. 12B. FIG. 12B is a schematic planar diagram of the fourth conductive layer in FIG. 12A. In an exemplary implementation, the fourth conductive layer may be referred to as a second source-drain metal (SD2) layer.

In an exemplary embodiment, the fourth conductive layer in each circuit unit includes at least a first power supply line 61, a data signal line 62 and an anode connection electrode 63.

In an exemplary implementation, the first power supply line 61 may be in a shape of a straight line or a bending line extending along the second direction Y, and the first power supply line 61 is connected to the first power supply connection block 42-1 through the twenty-first via V21. Since the first power supply connection block 42-1 is connected to the second connection electrode 42, and the second connection electrode 42 is connected to the first electrode of the fifth transistor T5 and the second plate 72 of the storage capacitor, the first power supply line 61 can write the first power supply signal to the fifth transistor T5 and the second plate 72 of the storage capacitor.

In the exemplary implementation, the data signal line 62 may be in a shape of a straight line or a bending line extending along the second direction Y, and the data signal line 62 is connected to the third connection electrode 43 through the twenty-second via V22. Since the third connection electrode 43 is connected to the first region of the fourth active layer, it is realized that the data signal line 62 is connected to a first electrode of the fourth transistor T4, and the data signal line 62 can write a data signal to the first electrode of the fourth transistor T4.

In an exemplary implementation, the anode connection electrode 63 may be in a shape of a strip extending along the second direction Y, the anode connection electrode 63 is connected to the fourth connection electrode 44 through the twenty-third via V23, and the anode connection electrode 63 is configured to be connected to the anode to be formed subsequently. Since the fourth connection electrode 44 is connected to the second region of the sixth active layer and a second region of the seventh active layer, connection between the anode to be formed subsequently and the second electrode of the sixth transistor T6 as well as the second electrode of the seventh transistor T7 can be achieved, and the pixel drive circuit can drive the light emitting device to emit light.

In an exemplary implementation, the fourth conductive layer may further include a first connection line 81 and a second connection line 82.

In an exemplary implementation, the first connection line 81 may be in a shape of a straight line or a bending line extending along the second direction Y, and the first connection line 81 is connected to the eighth connection electrode 48 through the twenty-fourth via V24. Since the eighth connection electrode 48 is connected to the first initial signal line 31, the interconnection between the first initial signal line 31 whose main body portion extends along the first direction X and the first connection line 81 whose main body portion extends along the second direction Y is realized, and a net-like connecting structure is formed on the display substrate. In the present disclosure, by providing the first initial signal line 31 and the first connection line 81 to form the net-like connecting structure, not only resistances of the signal lines can be effectively reduced and a voltage drop of the first initial signal is reduced, but also uniformity of the first initial signal in the display substrate can be effectively improved, the display uniformity can be effectively improved, and the display effect and the display quality can be improved.

In an exemplary implementation, the second connection line 82 may be in a shape of a straight line or a bending line extending along the second direction Y, and the second connection line 82 is connected to the initial connection block 46-1 through the twenty-fifth via V25. Since the initial connection block 46-1 is connected to the sixth connection electrode 46, and the sixth connection electrode 46 is connected to the second initial signal line 32, the interconnection of the second initial signal line 32 whose main body portion extends along the first direction X and the second connection line 82 whose main body portion extends along the second direction Y is realized, and a net-like connecting structure is formed on the display substrate. In the present disclosure, by providing the second initial signal line 32 and the second connection line 82 to form the net-like connecting structure, not only the resistances of the signal lines can be effectively reduced and a voltage drop of the second initial signal is reduced, but also uniformity of the second initial signal in the display substrate can be effectively improved, the display uniformity can be effectively improved, and the display effect and the display quality can be improved.

FIG. 12C is a schematic diagram of a net-like connecting structure of a first initial signal according to an exemplary embodiment of the present disclosure, FIG. 12D is a schematic diagram of a net-like connecting structure of a second initial signal according to an exemplary embodiment of the present disclosure, and FIG. 12E is a schematic diagram of a net-like connecting structure of a first initial signal and a net-like connecting structure of a second initial signal according to an exemplary embodiment of the present disclosure.

As shown in FIGS. 12C and 12E, the first initial signal line 31 may be connected to the eighth connection electrode 48, and a first connection block 81-1 may be provided on the first connection line 81. The first connection block 81-1 may be in a shape of a strip extending along the first direction X, a first end of the first connection block 81-1 is connected to the first connection line 81, and a second end of the first connection block 81-1 is connected to the eighth connection electrode 48 through a via, thus realizing the interconnection between the first initial signal line 31 whose main body portion extends along the first direction X and the first connection line 81 whose main body portion extends along the second direction Y, and forming a net-like connecting structure for a first initial signal on the display substrate.

In an exemplary implementation, the first connection line 81 and the first connection block 81-1 may be of an interconnected integral structure.

As shown in FIGS. 12D and 12E, a second connection block 82-1 may be provided on the second connection line 82. The second connection block 82-1 may be in a shape of a block, a first end of the second connection block 82-1 is connected to the second connection line 82, a second end of the second connection block 82-1 is connected to the initial connection block 46-1 through a via, and the initial connecting block 46-1 is connected to the second initial signal line 32 through a via, thereby realizing the interconnection between the second initial signal line 32 whose main body portion extending along the first direction X and the second connection line 82 whose main body portion extending along the second direction Y, and forming a net-like connecting structure for a second initial signal on the display substrate.

In an exemplary implementation, the connection line 82 and the second connection block 82-1 may be of an interconnected integral structure.

As shown in FIG. 12E, the first initial signal line 31, the initial connection block 46-1, and the eighth connection electrode 48 may be disposed in the third conductive layer, the second initial signal line 32 may be disposed in the second conductive layer, and the first connection line 81 and the second connection line 82 may be disposed in the fourth conductive layer.

In an exemplary implementation, the first connection line 81 and the second connection line 82 may be disposed in different circuit units. For example, the first connection line 81 may be disposed in the circuit units of the (N+1)-th unit column and the (N+3)-th unit column, and the second connection line 82 may be disposed in the circuit units of the N-th unit column and the (N+2)-th unit column. As another example, the first connection line 81 may be disposed in the circuit units of the N-th unit column and the (N+2)-th unit column, and the second connection line 82 may be disposed in the circuit units of the (N+1)-th unit column and the (N+3)-th unit column.

In an exemplary implementation, the first initial signal line 31 and the second initial signal line 32 may be disposed in each unit row, and the first connection line 81 and the second connection line 82 may be alternately disposed in a plurality of unit columns, which can fully utilize layout space, avoid affecting light transmittance to the provision of the first connection line 81 and the second connection line 82, and improve the display effect.

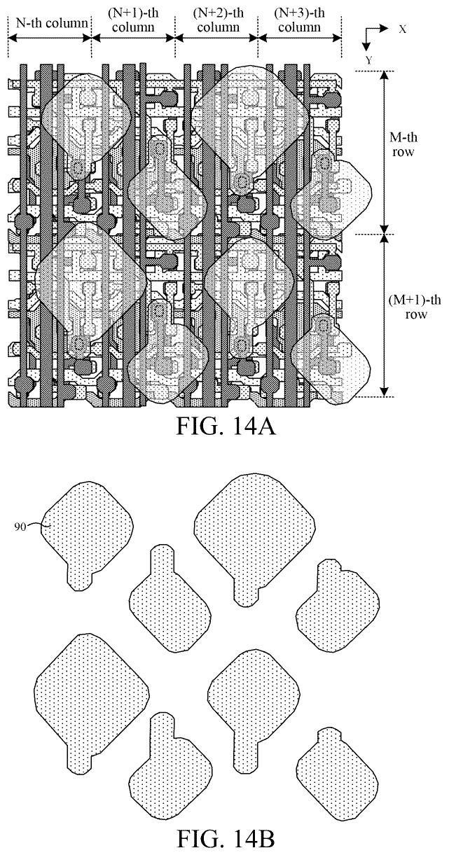

(18) A pattern of a second planarization layer is formed. In an exemplary implementation, forming the pattern of the second planarization layer may include coating a second planarization film on the base substrate on which the above-mentioned patterns are formed, patterning the second planarization film using a patterning process to form the second planarization layer covering the fourth conductive layer, wherein the second planarization layer is provided with a plurality of vias, as shown in FIG. 13.

In an exemplary implementation, the plurality of vias in each circuit unit at least include an anode via V30.

In an exemplary implementation, an orthographic projection of the anode via V30 on the base substrate is within a range of an orthographic projection of the anode connection electrode 63 on the base substrate, the second planarization layer within the anode via V30 is removed to expose a surface of the anode connection electrode 63, and the anode via V30 is configured such that the anode to be formed subsequently is connected to the anode connection electrode 63 through the anode via V30.

So far, a drive circuit layer has been manufactured on the base substrate. In a plane parallel to the display substrate, the drive circuit layer may include a plurality of circuit units, each circuit unit may include a pixel drive circuit, and a first scan signal line, a second scan signal line, a third scan signal line, a first signal line, a second signal line, a data signal line, a first power supply line, a first initial signal line, and a second initial signal line connected to the pixel drive circuit. In a plane perpendicular to the display substrate, the drive circuit layer may include a first insulation layer, a semiconductor layer, a second insulation layer, a first conductive layer, a third insulation layer, a second conductive layer, a fourth insulation layer, a third conductive layer, a first planarization layer, a fourth conductive layer and the second planarization layer which are stacked sequentially on the base substrate.

In an exemplary implementation, after preparation of the drive circuit layer is completed, a light emitting structure layer is prepared on the drive circuit layer, and a preparation process of the light emitting structure layer may include following operations.

(19) A pattern of an anode conductive layer is formed. In an exemplary implementation, forming the pattern of the anode conductive layer may include: depositing an anode conductive thin film on the base substrate on which the above-mentioned patterns are formed, patterning the anode conductive thin film by a patterning process to form an anode conductive layer on the second planarization layer, as shown in FIGS. 14A and 14B, and FIG. 14B is a schematic plan view of the anode conductive layer in FIG. 14A.

In an exemplary implementation, the anode conductive layer may include a plurality of anodes 90, and each anode 90 may be connected to an anode connection electrode 63 of a corresponding circuit unit through the anode via V30. Since the anode connection electrode 63 is connected to the fourth connection electrode 44, and the fourth connection electrode 44 is connected to the second region of the sixth active layer and the second region of the seventh active layer, corresponding connection between the light emitting device and the pixel drive circuit is realized, and the pixel drive circuit can drive the light emitting device to emit light.

In an exemplary implementation, the plurality of anodes 90 may include a first anode of a red light emitting device, a second anode of a first green light emitting device, a third anode of a blue light emitting device, and a fourth anode of a second green light emitting device. The first anode, the second anode, the third anode, and the fourth anode may be sequentially disposed along the first direction X, and the first anodes, the second anodes, the third anodes, and the fourth anodes of adjacent rows are staggered to form an RGBG pixel arrangement.

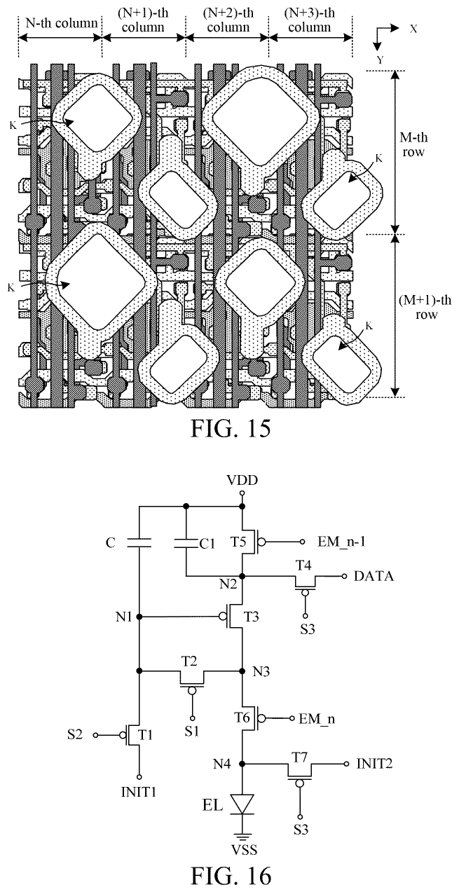

(20) A pattern of a pixel definition layer is formed. In an exemplary implementation, forming the pattern of the pixel definition layer may include: coating a pixel definition thin film on the base substrate on which the aforementioned patterns are formed; the pixel definition thin film is patterned through a patterning process, so as to form a pattern of a pixel definition layer, as shown in FIG. 15.

In an exemplary implementation, the pixel definition layer may include a plurality of pixel openings K, each of which may expose a surface of an anode 90.

In an exemplary implementation, a subsequent preparation process may include: forming an organic emitting layer using an evaporation or inkjet printing process, wherein the organic emitting layer is connected to an anode through a pixel opening, and forming a cathode on the organic emitting layer, wherein the cathode is connected to the organic emitting layer. An encapsulation structure layer is formed, and the encapsulation structure layer may include a first encapsulation layer, a second encapsulation layer, and a third encapsulation layer that are stacked, wherein the first encapsulation layer and the third encapsulation layer may be made of an inorganic material, the second encapsulation layer may be made of an organic material, and the second encapsulation layer is arranged between the first encapsulation layer and the third encapsulation layer, so that it may be ensured that external moisture cannot enter a light emitting structure layer.

In an exemplary implementation, the base substrate may be a flexible substrate, or a rigid substrate. The rigid substrate may be made of, but is not limited to, one or more of glass and quartz. The flexible substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. In an exemplary implementation, the flexible substrate may include a first flexible material layer, a first inorganic material layer, a semiconductor layer, a second flexible material layer, and a second inorganic material layer which are stacked, wherein materials of the first flexible material layer and the second flexible material layer may be Polyimide (P1), Polyethylene Terephthalate (PET), or a surface-treated polymer soft film, or the like, materials of the first inorganic material layer and the second inorganic material layer may be Silicon Nitride (SiNx) or Silicon Oxide (SiOx), or the like, for improving a water and oxygen resistance capability of the base substrate, and a material of the semiconductor layer may be amorphous silicon (a-si).

In an exemplary implementation, the first conductive layer, the second conductive layer, the third conductive layer, and the fourth conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo. The anode conductive layer may be made of a single-layer structure, such as indium tin oxide ITO or indium zinc oxide IZO, or may be made of a multi-layer composite structure, such as ITO/Ag/ITO, etc. The first insulation layer, the second insulation layer, the third insulation layer, and the fourth insulation layer may be made of any one or more of Silicon Oxide (SiOx), Silicon Nitride (SiNx), and Silicon Oxynitride (SiON), and may be a single layer, multiple layers, or a composite layer. The first planarization layer and the second planarization layer may be made of an organic material, such as resin. The pixel definition layer may be made of polyimide, acrylic or polyethylene terephthalate. The cathode may be made of any one or more of magnesium (Mg), silver (Ag), aluminum (Al), copper (Cu) and lithium (Li), or an alloy made of any one or more of the above metals.

An exemplary embodiment of the present disclosure provides a display substrate in which pulse width modulation with a higher accuracy at an ultra-high frequency, light emitting signal duty compensation, low gray scale compensation, and improved afterimage can be realized by separate control of a fifth transistor and a sixth transistor. The fifth transistor T5 is connected to a first signal line, the sixth transistor T6 is connected to a second signal line, and the first signal line and the second signal line jointly adjust duty of a pulse width modulation (PWM).

The display substrate of the present disclosure facilitates realization of separate control of the fifth transistor T5 and the sixth transistor T6 by providing the first signal line and the second signal line in different conductive layers, providing the first signal line and the second signal line at two sides of the third transistor T3 in the second direction, and providing the fifth transistor T5 and the sixth transistor T6 at two sides of the third transistor T3 in the first direction and the second direction.

In the display substrate of the present disclosure, by providing the first node of the pixel drive circuit to be overlapped with the first scan signal line and the first signal line, respectively, the coupling influence to which the first node is subjected can be complemented by the jumping of the two signal lines.

The display substrate of the present disclosure is provided with a first initial signal line whose main body portion extends along the first direction and a first connection line whose main body portion extends along the second direction, and a second initial signal line whose main body portion extends along the first direction and a second connection line whose main body portion extends along the second direction, so that the first initial signal line and the second initial signal line form a net-like connecting structure, respectively, which not only effectively reduces resistances of the initial signal lines and reduces a voltage drop of the initial voltages, but also effectively improves the uniformity of the initial voltage in the display substrate, effectively improves the display uniformity, and improves the display effect and the display quality.

In the display substrate of the present disclosure, by providing a node shielding electrode, the influence of signals in the pixel drive circuit on the node between the two gate electrodes of the second transistor T2 is reduced, and electrical performance of the second transistor T2 is ensured.

The manufacturing process in the present disclosure may be compatible well with an existing manufacturing process, is simple in process implementation, is easy to implement, and has a high production efficiency, a low production cost, and a high yield.

FIG. 16 is an equivalent circuit diagram of another pixel drive circuit according to an exemplary embodiment of the present disclosure. As shown in FIG. 16, a main structure of the pixel drive circuit according to an embodiment of the present disclosure is substantially the same as that shown in FIG. 4, except that the pixel drive circuit of the present embodiment further includes a first capacitor C1, a first end of the first capacitor C1 is connected to the first power supply line VDD, and a second end of the first capacitor C1 is connected to the second node N2.

In an exemplary implementation, a gate electrode of the fifth transistor T5 in the pixel drive circuit of the present embodiment is connected to a light emitting signal line EM_n-1 in the previous unit row, and a gate electrode of the sixth transistor T6 is connected to a light emitting signal line EM_n in the present unit row, thereby realizing separate control of the fifth transistor T5 and the sixth transistor T6.

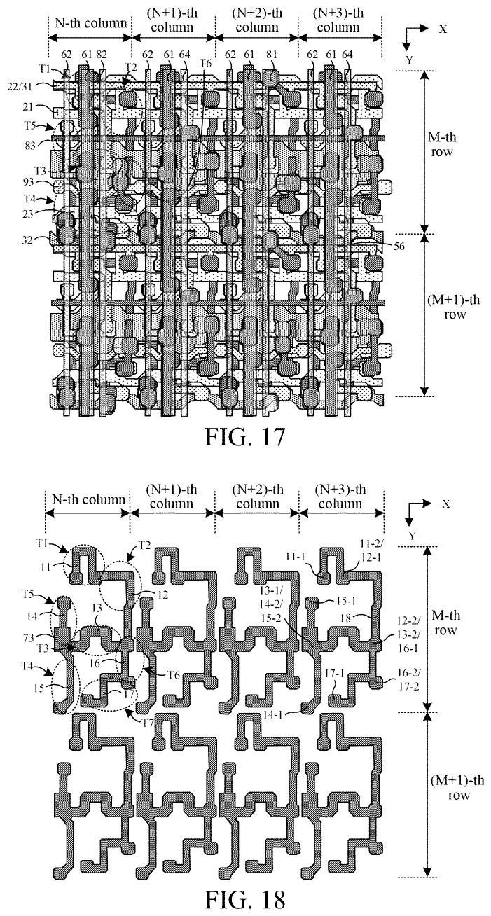

FIG. 17 is a schematic diagram of a structure of a display substrate according to an exemplary embodiment of the present disclosure, and illustrates a planar structure of eight circuit units (2 unit rows and 4 unit columns). In an exemplary implementation, the main structure of the display substrate of the present embodiment is substantially the same as that shown in FIG. 5, except that only one light emitting signal line is provided in the display unit of the present embodiment, and the light emitting signal line is connected to a gate electrode of the sixth transistor T6 in the present unit row on the one hand, and to a gate electrode of a fifth transistor T5 in the next unit row on the other hand.

In an exemplary implementation, at least one circuit unit may include a pixel drive circuit connected to a first power supply line 61 and a light emitting signal line 93, respectively, and the light emitting signal line 93 is configured to provide a light emitting control signal to the sixth transistor T6 in the present unit row and the fifth transistor T5 in the next unit row.

In an exemplary implementation, at least one pixel drive circuit may include a first transistor T1, a second transistor T2, a third transistor T3, a fourth transistor T4, a fifth transistor T5, a sixth transistor T6, and a seventh transistor T7, and the positions and connection relationships of the above transistors are substantially the same as those in the foregoing embodiments.

In an exemplary implementation, the light emitting signal line 93 may be in a shape of a straight line or a bending line whose main body portion extends along the first direction X, and the light emitting signal line 93 may be disposed at a side of the third transistor T3 in the second direction Y.

In an exemplary implementation, the fifth transistor T5 may at least include a fifth gate electrode, the sixth transistor T6 may at least include a sixth gate electrode, the fifth gate electrode may serve as the first gate of the present disclosure, and the sixth gate electrode may serve as the second gate of the present disclosure. In at least one circuit unit, the light emitting signal line 93 is connected to a sixth gate electrode in the present unit row, and the light emitting signal line 93 is connected to a fifth gate electrode in the next unit row through the light emitting signal connection line 56.

In an exemplary implementation, in a direction perpendicular to the display substrate, the display substrate may include a plurality of conductive layers. The fifth gate electrode and the sixth gate electrode may be disposed in a same conductive layer, the fifth gate electrode (the sixth gate electrode) and the light emitting signal line 93 may be disposed in different conductive layers, the fifth gate electrode (the sixth gate electrode) and the light emitting signal connection line 56 may be disposed in different conductive layers, and the light emitting signal connection line 56 and the light emitting signal line 93 may be disposed in different conductive layers.

In an exemplary implementation, the plurality of conductive layers may at least include a first conductive layer, a second conductive layer, a third conductive layer, and a fourth conductive layer sequentially disposed on the base substrate along a direction away from the base substrate. The fifth gate electrode and the sixth gate electrode may be disposed in the first conductive layer, the light emitting signal line 93 may be disposed in the third conductive layer, and the light emitting signal connection line 56 may be disposed in the fourth conductive layer.

In an exemplary implementation, the light emitting signal line 93 may be connected to the sixth gate electrode through a via, the light emitting signal connection line 56 may be in a shape of a strip extending along the second direction Y. A first end of the light emitting signal connection line 56 is connected to the light emitting signal line 93 in the present unit row through the via, and a second end of the light emitting signal connection line 56, after extending from the present unit row to the next unit row, is connected to the fifth gate electrode in the next unit row through a via.

In an exemplary implementation, the plurality of conductive layers may further include a fifth conductive layer disposed on a side of the fourth conductive layer away from the base substrate, the first power supply line 61 may be disposed in the fifth conductive layer, and an orthographic projection of the first power supply line 61 on the plane of the display substrate is at least partially overlapped with an orthographic projection of the light emitting signal connection line 56 on the plane of the display substrate.

In an exemplary implementation, at least one circuit unit may include a first initial signal line 31 extending along the first direction X and a first connection line 81 extending along the second direction Y, and the first connection line 81 is connected to the first initial signal line 31 to form a net-like connecting structure for transmitting a first initial signal on the display substrate.

In an exemplary implementation, at least one circuit unit may include a second initial signal line 32 extending along the first direction X and a second connection line 82 extending along the second direction Y, and the second connection line 82 is connected to the second initial signal line 32 to form a net-like connecting structure for transmitting a second initial signal on the display substrate.

In an exemplary implementation, at least one circuit unit may include a third connection line 83 extending along the first direction X and a second power supply line 64 extending along the second direction Y, and the third connection line 83 is connected to the second power supply line 64 to form a net-like connecting structure that transmits a second power supply signal on the display substrate.

In an exemplary embodiment, taking eight circuit units (two unit rows and fourth unit columns) as an example, the manufacturing process for the display substrate of the present embodiment may include the following operations.

(21) A pattern of a semiconductor layer is formed, the process of forming the pattern of the semiconductor layer and the structure of the semiconductor layer are substantially the same as those shown in FIG. 6, and the semiconductor layer may include a first active layer 11 to a seventh active layer 17, except that the first active layer 11 to the seventh active layer 17 are of an interconnected integral structure, and the semiconductor layer further includes a third plate 73 of the first capacitor, as shown in FIG. 18.

In an exemplary implementation, a second region 13-2 of the third active layer may simultaneously serve as a second region 12-2 of the second active layer and a first region 16-1 of the sixth active layer, i.e., the second region 12-2 of the second active layer, the second region 13-2 of the third active layer, and the first region 16-1 of the sixth active layer are connected to each other. Unlike the lack of connection between the second active layer and the third active layer shown in FIG. 6, the second region 12-2 of the second active layer and the second region 13-2 of the third active layer in the present embodiment are connected by an active connection line 18, that is, one end of the active connection line 18 is connected to the second region 12-2 of the second active layer 12, and the other end of the active connection line 18 is connected to the second region 13-2 of the third active layer 13, and the second active layer 12, the third active layer 13, and the active connection line 18 are of an interconnected integral structure.

In an exemplary implementation, the third plate 73 may be in a shape of a block (such as a rectangle), and may be disposed at a side of the third active layer 13 of the present circuit unit away from the (N+1)-th unit column, and the third plate 73 is connected to the first region 13-1 of the third active layer, the second region 14-2 of the fourth active layer, and the second region 15-2 of the fifth active layer respectively. In an exemplary implementation, the third plate 73 may serve as a plate of the first capacitor.

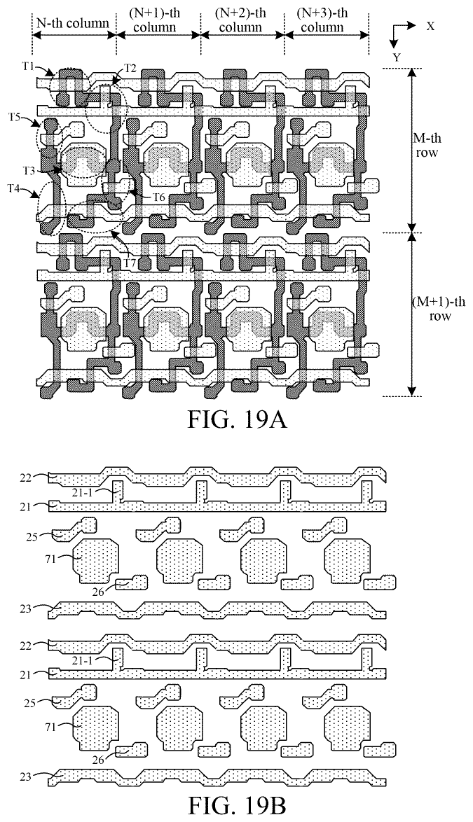

(22) A pattern of a first conductive layer is formed, the process of forming the pattern of the first conductive layer and the structure of the first conductive layer are substantially the same as those shown in FIGS. 7A and 7B, except that the first conductive layer is provided with a fifth gate electrode 25 without a light emitting signal line, as shown in FIGS. 19A and 19B, and FIG. 19B is a schematic plan view of the first conductive layer in FIG. 19A.

In an exemplary implementation, the pattern of the first conductive layer in each circuit unit may include a first scan signal line 21, a second scan signal line 22, a third scan signal line 23, a fifth gate electrode 25, a sixth gate electrode 26, and a first plate 71 of the storage capacitor, and the structures of the first scan signal line 21 to the third scan signal line 23, the sixth gate electrode 26, and the first plate 71 are substantially the same as those of the foregoing embodiments.

In an exemplary implementation, the fifth gate electrode 25 may be in a shape of a strip extending along the first direction X, the fifth gate electrode 25 may be located between the first scan signal line 21 and the first plate 71, and a region where the fifth gate electrode 25 is overlapped with the fifth active layer may serve as a gate electrode of the fifth transistor T5. In an exemplary implementation, the fifth gate electrode 25 is configured to be connected to a light emitting signal connection line to be formed subsequently, and the sixth gate electrode 26 is configured to be connected to the light emitting signal line to be formed subsequently.

In an exemplary implementation, an orthographic projection of the first plate 71 on the base substrate and an orthographic projection of the third plate 73 on the base substrate do not overlap.

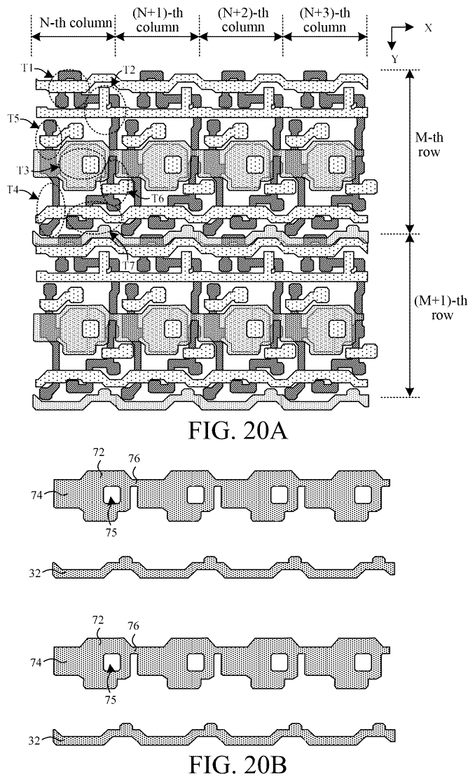

(23) A pattern of a second conductive layer is formed, the process of forming the pattern of the second conductive layer and the structure of the second conductive layer are substantially the same as those shown in FIGS. 8A and 8B, except that the second conductive layer is further provided with a fourth plate 74 of the first capacitor, as shown in FIGS. 20A and 20B, and FIG. 20B is a schematic plan view of the second conductive layer in FIG. 20A.

In an exemplary implementation, the pattern of the second conductive layer of each circuit unit may at least include a second initial signal line 32, a second plate 72 of the storage capacitor, and a fourth plate 74 of the first capacitor, and the structures of the second initial signal line 32 and the second plate 72 are substantially the same as those in the foregoing embodiments.

In an exemplary implementation, the fourth plate 74 may be in a shape of a rectangle, a chamfer may be provided at a corner of the rectangle, the fourth plate 74 may be disposed at a side of the second plate 72 of the present circuit unit away from the (N+1)-th unit column, an orthographic projection of the fourth plate 74 on the base substrate is at least partially overlapped with an orthographic projection of the third plate 73 on the base substrate, the fourth plate 74 may serve as another plate of the first capacitor, and the third plate 73 and the fourth plate 74 constitute the first capacitor of the pixel drive circuit.

In an exemplary implementation, the second plate 72 and the fourth plate 74 of each circuit unit may be of an interconnected integral structure.

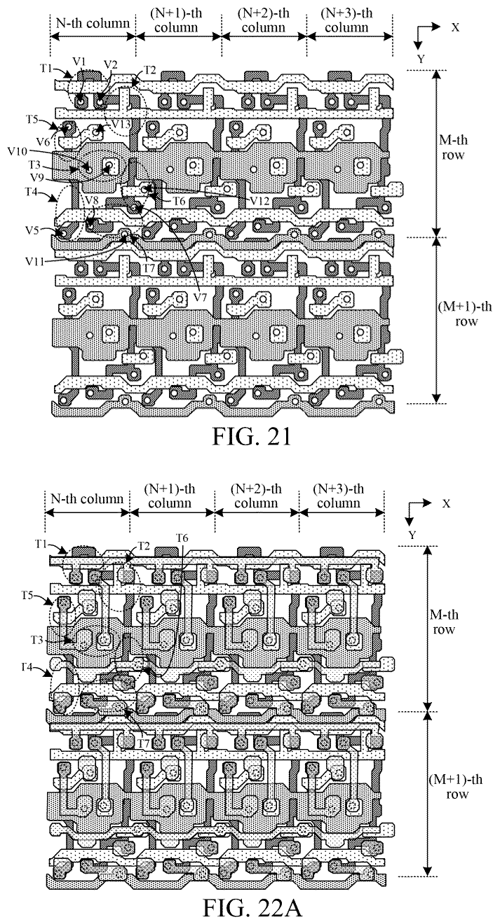

(24) A pattern of a fourth insulation layer is formed, the process of forming the pattern of the fourth insulation layer and the structure of the plurality of vias are substantially the same as those shown in FIG. 9, except that the plurality of vias further include a thirteenth via V13, but do not include a third via and a fourth via, as shown in FIG. 21.

In an exemplary implementation, the plurality of vias in each circuit unit may at least include a first via V1, a second via V2, a fifth via V5, a sixth via V6, a seventh via V7, an eighth via V8, a ninth via V9, a tenth via V10, an eleventh via V11, a twelfth via V12, and the thirteenth via V13.

The positions and connecting structures of the first via V1 to the second via V2 and the fifth via V5 to the twelfth via V12 are substantially the same as those in the aforementioned embodiments.

In an exemplary implementation, an orthographic projection of the thirteenth via V13 on the base substrate is within a range of an orthographic projection of the fifth gate electrode 25 on the base substrate, the fourth insulation layer and the third insulation layer within the thirteenth via V13 are etched away to expose a surface of the fifth gate electrode 25, and the thirteenth via V13 is configured such that a ninth connection electrode to be formed subsequently is connected to the fifth gate electrode 25 through the thirteenth via V13.

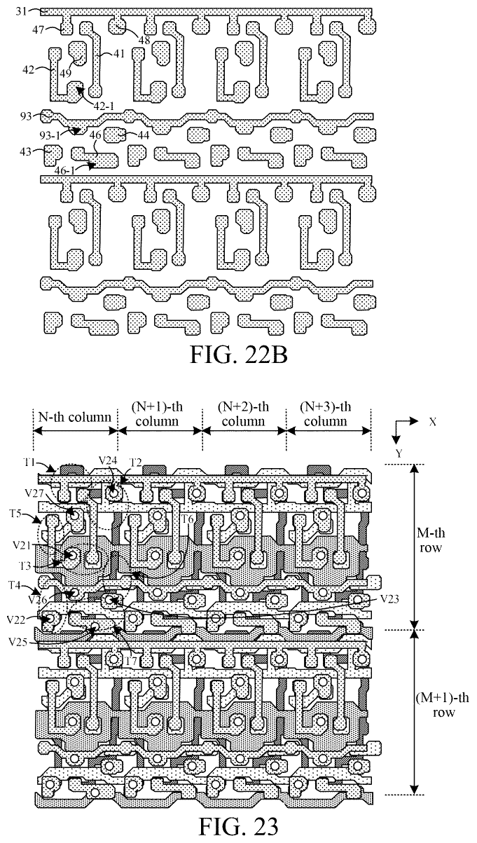

(25) A pattern of a third conductive layer is formed, the process of forming the third conductive layer, and the structure of the third conductive layer are substantially the same as those shown in FIGS. 10A and 10B, except that the third conductive layer is further provided with a ninth connection electrode 49, without a fifth connection electrode, as shown in FIGS. 22A and 22B, and FIG. 22B is a schematic plan view of the third conductive layer in FIG. 22A.

In an exemplary implementation, the third conductive layer in each circuit unit may at least include a first initial signal line 31, a light emitting signal line 93, a first connection electrode 41, a second connection electrode 42, a third connection electrode 43, a fourth connection electrode 44, a sixth connection electrode 46, a seventh connection electrode 47, an eighth connection electrode 48, and a ninth connection electrode 49, and structures of the first initial signal line 31, the first connection electrode 41 to the fourth connection electrode 44, and the sixth connection electrode 46 to the eighth connection electrode 48 are substantially the same as those in the foregoing embodiments.

In an exemplary implementation, the light emitting signal line 93 may be in a shape of a straight line or a bending line extending along the first direction X, the light emitting signal line 93 may be located between the third scan signal line 23 and the second plate 72, and the light emitting signal line 93 may be connected to the sixth gate electrode 26 of each circuit unit through the twelfth via V12 of each circuit unit, so that the light emitting signal line 93 may control turn-on and turn-off of the sixth transistor T6.

In an exemplary implementation, a light emitting connection block 93-1 may be further provided on a side of the light emitting signal line 93 away from the second plate 72, the light emitting connection block 93-1 may be in a shape of a block (such as a rectangle). A first end of the light emitting connection block 93-1 is connected to the light emitting signal line 93, a second end of the light emitting connection block 93-1 extends in a direction away from the second plate 72, and the light emitting connection block 93-1 is configured to be connected to the light emitting signal connection line to be formed subsequently.

In an exemplary implementation, an orthographic projection of the first connection electrode 41 on the base substrate is at least partially overlapped with an orthographic projection of the first scan signal line 21 on the base substrate.

In an exemplary implementation, a first power supply connection block 42-1 may be provided at a second end of the second connection electrode 42, the first power supply connection block 42-1 may be in a shape of a block (such as a rectangle), an orthographic projection of the first power supply connection block 42-1 on the base substrate may be within a range of an orthographic projection of the second plate 72 on the base substrate, and the first power supply connection block 42-1 is configured to be connected to a first power supply line to be formed subsequently.

In an exemplary implementation, an initial connection block 46-1 may be provided in the circuit units of the N-th unit column, and the initial connection block 46-1 is configured to be connected to a second connection line to be formed subsequently.

In an exemplary implementation, the ninth connection electrode 49 may be in a shape of a block (such as a rectangle), the ninth connection electrode 49 may be disposed between the first initial signal line 31 and the second plate 72, the ninth connection electrode 49 is connected to the fifth gate electrode 25 through the thirteenth via V13, and the ninth connection electrode 49 is configured to be connected to the light emitting signal connection line to be formed subsequently.

(26) A pattern of a first planarization layer is formed. In an exemplary implementation, forming the pattern of the first planarization layer may include coating a first planarization thin film on the base substrate on which the above-mentioned patterns are formed, patterning the first planarization thin film through a patterning process, to form a first planarization layer covering the third conductive layer, wherein the first planarization layer is provided with a plurality of vias, as shown in FIG. 23.

In an exemplary implementation, the plurality of vias on the first planarization layer at least includes a twenty-first via V21, a twenty-second via V22, a twenty-third via V23, a twenty-fourth via V24, a twenty-fifth via V25, a twenty-sixth via V26, and a twenty-seventh via V27.

In an exemplary implementation, an orthographic projection of the twenty-first via V21 on the base substrate is within a range of an orthographic projection of the first power supply connection block 42-1 on the base substrate, the first planarization layer within the twenty-first via V21 is removed to expose a surface of the first power supply connection block 42-1, and the twenty-first via V21 is configured such that an eleventh connection electrode to be formed subsequently is connected to the first power supply connection block 42-1 through the twenty-first via V21. In an exemplary implementation, the twenty-first via V21 may be provided in each circuit unit.

In an exemplary implementation, the orthographic projection of the twenty-first via V21 on the base substrate may be within a range of an orthographic projection of the second plate 72 on the base substrate.

In an exemplary implementation, an orthographic projection of the twenty-second via V22 on the base substrate is within a range of an orthographic projection of the third connection electrode 43 on the base substrate, the first planarization layer within the twenty-second via V22 is removed to expose a surface of the third connection electrode 43, and the twenty-second via V22 is configured such that a twelfth connection electrode to be formed subsequently is connected to the third connection electrode 43 through the twenty-second via V22. In an exemplary implementation, the twenty-second via V22 may be provided in each circuit unit.

In an exemplary implementation, an orthographic projection of the twenty-third via V23 on the base substrate is within a range of an orthographic projection of the fourth connection electrode 44 on the base substrate, the first planarization layer within the twenty-third via V23 is removed to expose a surface of the fourth connection electrode 44, and the twenty-third via V23 is configured such that a thirteenth connection electrode to be formed subsequently is connected to the fourth connection electrode 44 through the twenty-third via V23. In an exemplary implementation, the twenty-third via V23 may be provided in each circuit unit.

In an exemplary implementation, an orthographic projection of the twenty-fourth via V24 on the base substrate is within a range of an orthographic projection of the eighth connection electrode 48 on the base substrate, the first planarization layer within the twenty-fourth via V24 is removed to expose a surface of the eighth connection electrode 48, and the twenty-fourth via V24 is configured such that a fourteenth connection electrode to be formed subsequently is connected to the eighth connection electrode 48 through the twenty-fourth via V24. In an exemplary implementation, the twenty-fourth via V24 may be provided in each circuit unit.

In an exemplary implementation, an orthographic projection of the twenty-fifth via V25 on the base substrate is within a range of an orthographic projection of the initial connection block 46-1 on the base substrate, the first planarization layer within the twenty-fifth via V25 is removed to expose a surface of the initial connection block 46-1, and the twenty-fifth via V25 is configured such that a fifteenth connection electrode to be formed subsequently is connected to the initial connection block 46-1 through the via. In an exemplary implementation, the twenty-fifth via V25 may be provided in the circuit units of the N-th unit column.

In an exemplary implementation, an orthographic projection of the twenty-sixth via V26 on the base substrate is within a range of an orthographic projection of the light emitting connection block 93-1 of the light emitting signal line 93 on the base substrate, the first planarization layer within the twenty-sixth via V26 is removed to expose a surface of the light emitting connection block 93-1, and the twenty-sixth via V26 is configured such that the light emitting signal connection line to be formed subsequently is connected to the light emitting connection block 93-1 through the twenty-sixth via V26. In an exemplary implementation, the twenty-sixth via V26 may be provided in each circuit unit.

In an exemplary implementation, an orthographic projection of the twenty-seventh via V27 on the base substrate is within a range of an orthographic projection of the ninth connection electrode 49 on the base substrate, the first planarization layer within the twenty-seventh via V27 is removed to expose a surface of the ninth connection electrode 49, and the twenty-seventh via V27 is configured such that the light emitting signal connection line to be formed subsequently is connected to the ninth connection electrode 49 through the twenty-seventh via V27. In an exemplary implementation, the twenty-seventh via V27 may be provided in each circuit unit.

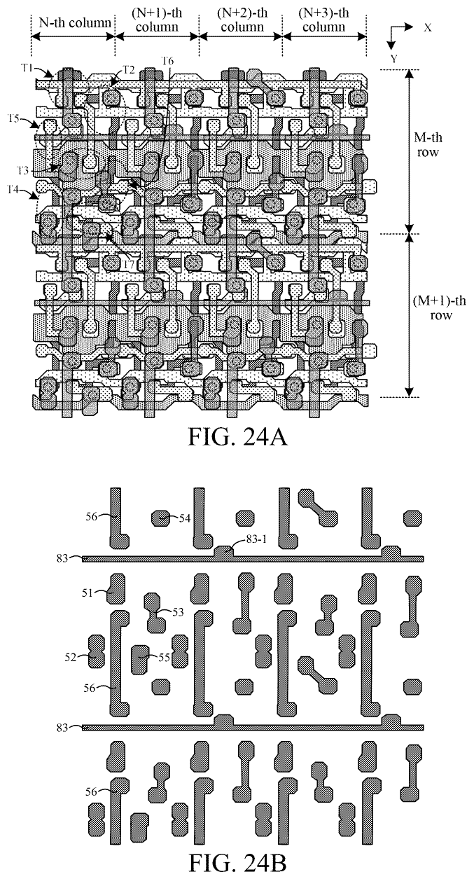

(27) A pattern of a fourth conductive layer is formed. In an exemplary implementation, forming the pattern of the fourth conductive layer may include: depositing a fourth conductive thin film on the base substrate on which the aforementioned patterns are formed, and patterning the fourth conductive thin film by a patterning process to form the fourth conductive layer arranged on the first planarization layer, as shown in FIG. 24A and FIG. 24B, FIG. 24B is a schematic planar diagram of the fourth conductive layer in FIG. 24A.

In an exemplary implementation, the fourth conductive layer at least includes an eleventh connection electrode 51, a twelfth connection electrode 52, a thirteenth connection electrode 53, a fourteenth connection electrode 54, a fifteenth connection electrode 55, a light emitting signal connection line 56, and a third connection line 83.

In an exemplary implementation, the eleventh connection electrode 51 may be in a shape of a block (such as a rectangle), the eleventh connection electrode 51 is connected to the first power supply connection block 42-1 through the twenty-first via V21, and the eleventh connection electrode 51 is configured to be connected to the first power supply line to be formed subsequently. In an exemplary implementation, the eleventh connection electrode 51 may be provided in each circuit unit.

In an exemplary implementation, an orthographic projection of the eleventh connection electrode 51 on the base substrate is at least partially overlapped with an orthographic projection of the second plate 72 on the base substrate.

In an exemplary implementation, the twelfth connection electrode 52 may be in a shape of a strip extending along the second direction Y, the twelfth connection electrode 52 is connected to the third connection electrode 43 through the twenty-second via V22, and the twelfth connection electrode 52 is configured to be connected to a data signal line to be formed subsequently. In an exemplary implementation, the twelfth connection electrode 52 may be provided in each circuit unit.

In an exemplary implementation, the thirteenth connection electrode 53 may be in a shape of a strip extending along the second direction Y, the thirteenth connection electrode 53 is connected to the fourth connection electrode 44 through the twenty-third via V23, and the thirteenth connection electrode 53 is configured to be connected to the anode connection electrode to be formed subsequently. In an exemplary implementation, the thirteenth connection electrode 53 may be provided in each circuit unit.

In an exemplary implementation, the fourteenth connection electrode 54 may be in a shape of a block (such as a rectangle) or a strip, and the fourteenth connection electrode 54 is connected to the eighth connection electrode 48 through the twenty-fourth via V24. In an exemplary implementation, the fourteenth connection electrode 54 may be provided in each circuit unit, the fourteenth connection electrode 54 in a circuit unit of the N-th unit column, the (N+1)-th unit column, and the (N+3)-th unit column is in a shape of a block (such as a rectangle), and the fourteenth connection electrode 54 in a shape of a block is a dummy-pad and is not connected to the fifth conductive layer to be formed subsequently, and the dummy-pad is configured to ensure etching uniformity and uniformity between sub-pixels. The fourteenth connection electrode 54 in the circuit unit of the (N+2)-th unit column has a shape of a strip, and the fourteenth connection electrode 54 of the (N+2)-th unit column is configured to be connected to a first connection line to be formed subsequently.

In an exemplary implementation, the fifteenth connection electrode 55 may be in a shape of a block (such as a rectangle), the fifteenth connection electrode 55 is connected to the initial connection block 46-1 through the twenty-fifth via V25, and the fifteenth connection electrode 55 is configured to be connected to the second connection line to be formed subsequently. In an exemplary implementation, the fifteenth connection electrode 55 may be provided in the circuit units of the N-th unit column.

In an exemplary implementation, the light emitting signal connection line 56 may be in a shape of a strip extending along the second direction Y, a first end of the light emitting signal connection line 56 is connected to the light emitting connection block 93-1 of the circuit unit in the present unit row through the twenty-sixth via V26, a second end of the light emitting signal connection line 56 extends along the second direction Y to the circuit unit in the next unit row, and is connected to a ninth connection electrode 49 of the circuit unit in the next unit row through the twenty-seventh via V27. In an exemplary implementation, the light emitting signal connection line 56 may be provided in each circuit unit.

In an exemplary implementation, since the light emitting connection block 93-1 of the circuit unit in the present unit row is connected to the light emitting signal line 93 in the present unit row and the ninth connection electrode 49 of the circuit unit in the next unit row is connected to the fifth gate electrode 25 of that circuit unit, the light emitting signal connection line 56 thus realizes a connection between the light emitting signal line 93 in the present unit row and the fifth gate electrode 25 in the next unit row, the light emitting signal line 93 in the present unit row can control not only the turn-on and turn-off of the sixth transistor T6 in the present unit row, but also turn-on and turn-off of the fifth transistor T5 in the next unit row, i.e., in the circuit unit of the present unit row, the fifth transistor T5 is controlled by the light emitting signal line 93 of the previous unit row, and the sixth transistor T6 is controlled by the light emitting signal line 93 of the present unit row. For example, the light emitting signal line 93 in the (M-1)-th unit row may control turn-on and turn-off of the sixth transistor T6 in the (M-1)-th unit row while controlling turn-on and turn-off of the fifth transistor T5 in the M-th unit row. As another example, the light emitting signal line 93 in the M-th unit row can control the turn-on and turn-off of the sixth transistor T6 in the M-th unit row while controlling turn-on and turn-off of the fifth transistor T5 in the (M+1)-th unit row, that is, in the circuit unit of the M-th unit row, the fifth transistor T5 is controlled by the light emitting signal line 93 in the (M-1)-th unit row and the sixth transistor T6 is controlled by the light emitting signal line 93 in the M-th unit row. For another example, the light emitting signal line 93 in the (M+1)-th unit row can control the turn-on and turn-off of the sixth transistor T6 in the (M+1)-th unit row while controlling turn-on and turn-off of the fifth transistor T5 in an (M+2)-th unit row.

In an exemplary implementation, the third connection line 83 may be in a shape of a straight line or a bending line extending along the first direction X, the third connection line 83 may be located between the first scan signal line 21 and the second plate 72, and the third connection line 83 is configured to be connected to a second power supply line to be formed subsequently.

In an exemplary implementation, a side of the third connection line 83 close to the first scan signal line 21 is connected to a second power supply connection block 83-1, the second power supply connection block 83-1 may be in a shape of a block (such as a rectangle), and the second power supply connection block 83-1 is configured to be connected to the second power supply line to be formed subsequently. In an exemplary implementation, the second power supply connection block 83-1 may be provided in the circuit units of the (N+1)-th unit column and the (N+3)-th unit column.

In an exemplary implementation, an orthographic projection of the third connection line 83 on the base substrate is not overlapped with an orthographic projection of the second plate 72 on the base substrate, and the orthographic projection of the third connection line 83 on the base substrate is at least partially overlapped with orthographic projections of the first connection electrode 41 and the second connection electrode 42 on the base substrate.

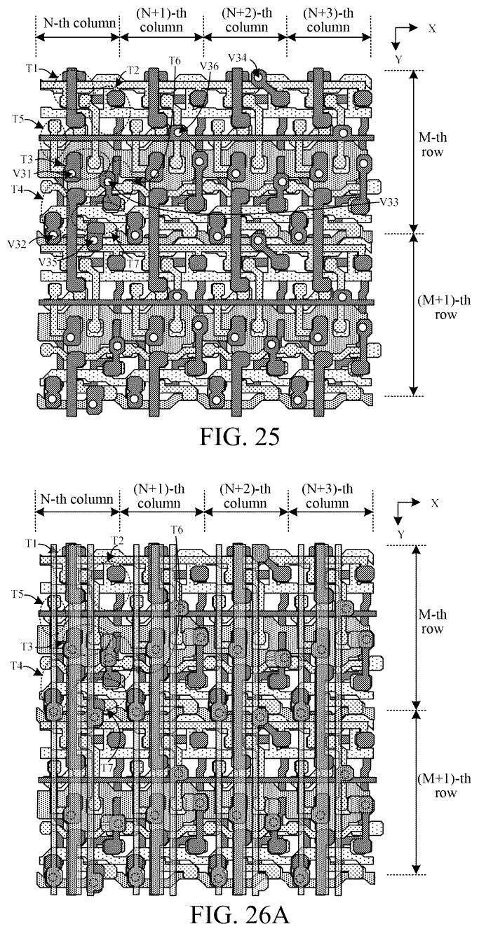

(28) A pattern of a second planarization layer is formed. In an exemplary implementation, forming the pattern of the second planarization layer may include coating a second planarization thin film on the base substrate on which the above-mentioned patterns are formed, patterning the second planarization thin film using a patterning process to form the second planarization layer covering the fourth conductive layer, wherein the second planarization layer is provided with a plurality of vias, as shown in FIG. 25.

In an exemplary implementation, the plurality of vias on the second planarization layer at least includes a thirty-first via V31, a thirty-second via V32, a thirty-third via V33, a thirty-fourth via V34, a thirty-fifth via V35, and a thirty-sixth via V36.

In an exemplary implementation, an orthographic projection of the thirty-first via V31 on the base substrate is within a range of an orthographic projection of the eleventh connection electrode 51 on the base substrate, the second planarization layer within the thirty-first via V31 is removed to expose a surface of the thirty-first via V31, and the thirty-first via V31 is configured such that the first power supply line to be formed subsequently is connected to the eleventh connection electrode 51 through the thirty-first via V31. In an exemplary implementation, the thirty-first via V31 may be provided in each circuit unit.

In an exemplary implementation, an orthographic projection of the thirty-second via V32 on the base substrate is within a range of an orthographic projection of the twelfth connection electrode 52 on the base substrate, the second planarization layer within the thirty-second via V32 is removed to expose a surface of the twelfth connection electrode 52, and the thirty-second via V32 is configured such that the data signal line to be formed subsequently is connected to the twelfth connection electrode 52 through the thirty-second via V32. In an exemplary implementation, the thirty-second via V32 may be provided in each circuit unit.

In an exemplary implementation, an orthographic projection of the thirty-third via V33 on the base substrate is within a range of an orthographic projection of the thirteenth connection electrode 53 on the base substrate, the second planarization layer within the thirty-third via V33 is removed to expose a surface of the thirteenth connection electrode 53, and the thirty-third via V33 is configured such that the anode connection electrode to be formed subsequently is connected to the thirteenth connection electrode 53 through the thirty-third via V33. In an exemplary implementation, the thirty-third via V33 may be provided in each circuit unit.

In an exemplary implementation, an orthographic projection of the thirty-fourth via V34 on the base substrate is within a range of an orthographic projection of the fourteenth connection electrode 54 on the base substrate, the second planarization layer within the thirty-fourth via V34 is removed to expose a surface of the fourteenth connection electrode 54, and the thirty-fourth via V34 is configured such that the first connection line to be formed subsequently is connected to the fourteenth connection electrode 54 through the thirty-fourth via V34. In an exemplary implementation, the thirty-fourth via V34 may be provided in the circuit units of the (N+2)-th unit column.

In an exemplary implementation, an orthographic projection of the thirty-fifth via V35 on the base substrate is within a range of an orthographic projection of the fifteenth connection electrode 55 on the base substrate, the second planarization layer within the thirty-fifth via V35 is removed to expose a surface of the fifteenth connection electrode 55, and the thirty-fifth via V35 is configured such that the second connection line to be formed subsequently is connected to the fifteenth connection electrode 55 through the thirty-fifth via V35. In an exemplary implementation, the thirty-fifth via V35 may be provided in the circuit units of the N-th unit column.

In an exemplary implementation, an orthographic projection of the thirty-sixth via V36 on the base substrate is within a range of an orthographic projection of the second power supply connection block 83-1 of the third connection line 83 on the base substrate, the second planarization layer within the thirty-sixth via V36 is removed to expose a surface of the second power supply connection block 83-1, and the thirty-sixth via V36 is configured such that the second power supply line to be formed subsequently is connected to the second power supply connection block 83-1 through the thirty-sixth via V36. In an exemplary implementation, the thirty-sixth via V36 may be provided in the circuit units of the (N+1)-th unit column and the (N+3)-th unit column.

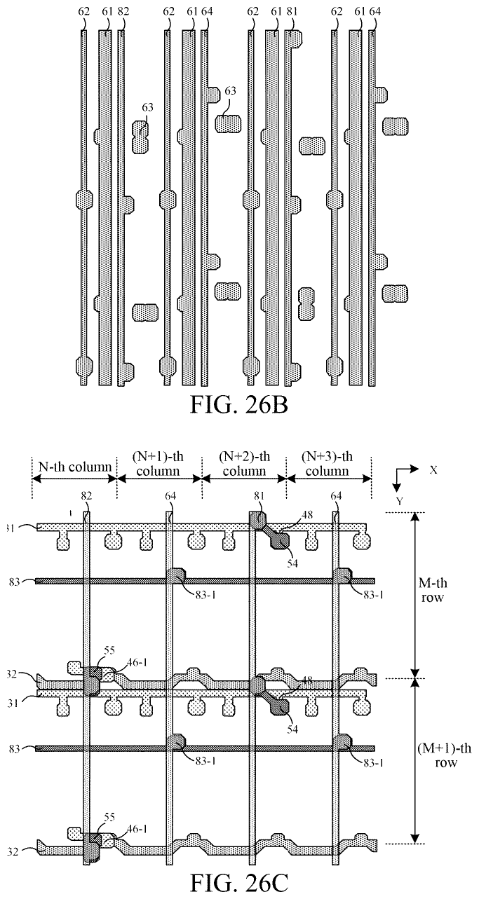

(29) A pattern of a fifth conductive layer is formed. In an exemplary implementation, forming the pattern of the fifth conductive layer may include: depositing a fifth conductive thin film on the base substrate on which the above-mentioned patterns are formed, and patterning the fifth conductive thin film using a patterning process to form the fifth conductive layer disposed on the second planarization layer, as shown in FIG. 26A and FIG. 26B, and FIG. 26B is a schematic plan view of the fifth conductive layer in FIG. 26A. In an exemplary implementation, the fifth conductive layer may be referred to as a third source-drain metal (SD3) layer.

In an exemplary implementation, the fifth conductive layer may at least include a first power supply line 61, a data signal line 62, an anode connection electrode 63, a second power supply line 64, a first connection line 81, and a second connection line 82.

In an exemplary implementation, the first power supply line 61 may be in a shape of a straight line or a bending line extending along the second direction Y, and the first power supply line 61 is connected to the eleventh connection electrode 51 through the thirty-first via V31. Since the eleventh connection electrode 51 is connected to the first power supply connection block 42-1, the first power supply connection block 42-1 is connected to the second connection electrode 42, and the second connection electrode 42 is connected to the first electrode of the fifth transistor T5, the second plate 72 of the storage capacitor, and the fourth plate 74 of the first capacitor, thus the first power supply line 61 can write the first power supply signal to the first electrode of the fifth transistor T5, the second plate 72 of the storage capacitor, and the fourth plate 74 of the first capacitor. In an exemplary implementation, the first power supply line 61 may be provided in each circuit unit.

In an exemplary implementation, an orthographic projection of the first power supply line 61 on the base substrate is at least partially overlapped with an orthographic projection of the light emitting signal connection line 56 on the base substrate, and the first power supply line 61 with a constant voltage can play a shielding role, can reduce influence of the light emitting signal on the pixel drive circuit, and can stabilize a potential of the light emitting signal.

In an exemplary implementation, the data signal line 62 may be in a shape of a straight line or a bending line extending along the second direction Y, and the data signal line 62 is connected to the twelfth connection electrode 52 through the thirty-second via V32. Since the twelfth connection electrode 52 is connected to the third connection electrode 43, and the third connection electrode 43 is connected to the first region of the fourth active layer, thus connection between the data signal line 62 and the first electrode of the fourth transistor T4 is realized, and the data signal line 62 can write a data signal to the first electrode of the fourth transistor T4. In an exemplary implementation, the data signal line 62 may be provided in each circuit unit.

In an exemplary implementation, the anode connection electrode 63 may be in a shape of a strip extending along the first direction X or along the second direction Y, the anode connection electrode 63 is connected to the thirteenth connection electrode 53 through the thirty-third via V33, and the anode connection electrode 63 is configured to be connected to an anode to be formed subsequently. Since the thirteenth connection electrode 53 is connected to the fourth connection electrode 44, and the fourth connection electrode 44 is connected to the second region of the sixth active layer and the second region of the seventh active layer, connection of the anode to be formed subsequently to the second electrode of the sixth transistor T6 and the second electrode of the seventh transistor T7 can be realized, and the pixel drive circuit can drive the light emitting device to emit light. In an exemplary implementation, the anode connection electrode 63 may be provided in each circuit unit.

In an exemplary implementation, the second power supply line 64 may be in a shape of a straight line or a bending line extending along the second direction Y, and the second power supply line 64 is connected to the second power supply connection block 83-1 through the thirty-sixth via V36. Since the second power supply connection block 83-1 is connected to the third connection line 83, interconnection between the third connection line 83 whose main body portion extends along the first direction X and the second power supply line 64 whose main body portion extends along the second direction Y is realized, and a net-like connecting structure is formed on the display substrate. In the present disclosure, the second power supply line 64 and the third connection line 83 form a net-like connecting structure, which not only can effectively reduce a resistance of the second power supply line and reduce a voltage drop of the second power supply signal, but also can effectively improve uniformity of the second power supply signal in the display substrate, effectively improve the display uniformity, and improve the display effect and the display quality. In an exemplary implementation, the second power supply line 64 may be provided in the circuit units of the (N+1)-th unit column and the (N+3)-th unit column.

In an exemplary implementation, the first connection line 81 may be in a shape of a straight line or a bending line extending along the second direction Y, and the first connection line 81 is connected to the fourteenth connection electrode 54 through the thirty-fourth via V34. Since the fourteenth connection electrode 54 is connected to the eighth connection electrode 48, and the eighth connection electrode 48 is connected to the first initial signal line 31, interconnection between the first initial signal line 31 whose main body portion extends along the first direction X and the first connection line 81 whose main body portion extends along the second direction Y is realized, and a net-like connecting structure is formed on the display substrate. In the present disclosure, the first initial signal line 31 and the first connection line 81 form a net-like connecting structure, which can not only effectively reduce resistances of the initial signal lines and reduce a voltage drop of the first initial signal, but also effectively improve the uniformity of the first initial signal in the display substrate, effectively improve the display uniformity and the display effect and the display quality. In an exemplary implementation, the first connection line 81 may be provided in the circuit units of the (N+2)-th unit column.

In an exemplary implementation, the second connection line 82 may be in a shape of a straight line or a bending line extending along the second direction Y, and the second connection line 82 is connected to the fifteenth connection electrode 55 through the thirty-fifth via V35. Since the fifteenth connection electrode 55 is connected to the initial connection block 46-1, the initial connection block 46-1 is connected to the sixth connection electrode 46, and the sixth connection electrode 46 is connected to the second initial signal line 32, interconnection between the second initial signal line 32 whose main body portion extend along the first direction X and the second connection line 82 whose main body portion extend along the second direction Y is realized, forming a net-like connecting structure on the display substrate. In the present disclosure, the second initial signal line 32 and the second connection line 82 form a net-like connecting structure, which can not only effectively reduce a resistance of the second signal line and reduce a voltage drop of the second initial signal, but also effectively improve uniformity of the second initial signal in the display substrate, effectively improve the display uniformity and the display effect and the display quality. In an exemplary implementation, the second connection line 82 may be provided in the circuit units of the N-th unit column.

FIG. 26C is a schematic diagram of a net-like connecting structure for an initial signal and a net-like connecting structure for a second power supply according to an exemplary embodiment of the present disclosure. As shown in FIG. 26C, a second power supply connection block 83-1 may be provided on the third connection line 83, and the second power supply line 64 is connected to the second power supply connection block 83-1 through a via, interconnection between the third connection line 83 whose main body portion extends along the first direction X and the second power supply line 64 whose main body portion extends along the second direction Y is realized, forming a net-like connecting structure for a second power supply on the display substrate. The first connection line 81 is connected to the fourteenth connection electrode 54 through a via, the fourteenth connection electrode 54 is connected to the eighth connection electrode 48 through a via, and the eighth connection electrode 48 is connected to the first initial signal line 31, interconnection between the first initial signal line 31 whose main body portion extends along the first direction X and the first connection line 81 whose main body portion extends along the second direction Y is realized, forming a net-like connecting structure for a first initial signal on the display substrate. The second connection line 82 is connected to the fifteenth connection electrode 55 through a via, the fifteenth connection electrode 55 is connected to the initial connection block 46-1 through a via, and the initial connection block 46-1 is connected to the second initial signal line 32, interconnection between the second initial signal line 32 whose main body portion extends along the first direction X and the second connection line 82 whose main body portion extends along the second direction Y is realized, forming a net-like connecting structure for a second initial signal on the display substrate.

In an exemplary implementation, the second initial signal line 32 may be disposed in the second conductive layer, the first initial signal line 31, the initial connection block 46-1, and the eighth connection electrode 48 may be disposed in the third conductive layer, the fourteenth connection electrode 54, the fifteenth connection electrode 55, and the third connection line 83 may be disposed in the fourth conductive layer, and the second power supply line 64, the first connection line 81, and the second connection line 82 may be disposed in the fifth conductive layer.

In an exemplary implementation, the first initial signal line 31, the second initial signal line 32, and the third connection line 83 may be disposed in each unit row, the first connection line 81, the second power supply line 64, the second connection line 82, and the second power supply line 64 may be alternately disposed in the unit columns, one first connection line 81, one second connection line 82, and two second power supply lines 64 are respectively disposed in four unit columns, and the first connection line 81, the second connection line 82, and the second power supply line 64 are disposed in different unit columns, which can fully utilize the layout space, avoid affecting a light transmittance, and improve the display effect.

In an exemplary implementation, the N-th unit column may be provided with a second connection line 82, the (N+1)-th unit column may be provided with a second power supply line 64, the (N+2)-th unit column may be provided with a first connection line 81, and the (N+3)-th unit column may be provided with a second power supply line 64.

(30) A pattern of a third planarization layer is formed. In an exemplary implementation, forming the pattern of the third planarization layer may include: coating a third planarization thin film on the base substrate on which the above-mentioned patterns are formed, patterning the third planarization thin film by a patterning process, to form a third planarization layer covering the fifth conductive layer, and the third planarization layer is provided with a plurality of anode vias, and an anode via is configured such that an anode to be formed subsequently is connected to the anode connection electrode through the via.

So far, a drive circuit layer has been manufactured on the base substrate. In a plane parallel to the display substrate, the drive circuit layer may include a plurality of circuit units, each of which may include a pixel drive circuit, and a first scan signal line, a second scan signal line, a third scan signal line, a light emitting signal line, a data signal line, a first power supply line, a first initial signal line, and a second initial signal line connected to the pixel drive circuit, and the light emitting signal lines is connected to the sixth transistor T6 in the present unit row and the fifth gate electrode 25 in the next unit row respectively. In a plane perpendicular to the display substrate, the drive circuit layer may include a first insulation layer, a semiconductor layer, a second insulation layer, a first conductive layer, a third insulation layer, a second conductive layer, a fourth insulation layer, a third conductive layer, a first planarization layer, a fourth conductive layer, a second planarization layer, a fifth conductive layer, and a third planarization layer that are sequentially stacked on the base substrate.

In an exemplary implementation, after the drive circuit layer is prepared, a light emitting structure layer is first prepared on the drive circuit layer, and then an encapsulation structure layer is formed. The light emitting structure layer may include an anode conductive layer, a pixel definition layer, an organic light emitting layer, and a cathode, the anode conductive layer may include a plurality of anodes, the pixel definition layer may include a plurality of pixel openings, and the encapsulation structure layer may include a first encapsulation layer, a second encapsulation layer, and a third encapsulation layer that are stacked.

The display substrate provided in the present embodiment also realizes separate control of the fifth transistor and the sixth transistor, and can realize pulse width modulation with a higher accuracy at an ultra-high frequency, light emitting signal duty compensation, low gray scale compensation, and improved afterimage. In at least one circuit unit of the present embodiment, the sixth transistor T6 is controlled by the light emitting signal line of the present unit row, and the fifth transistor T5 is controlled by a light emitting signal line of the previous unit row, that is, the fifth transistor T5 adopts the (cascaded) mode of being driven by a light emitting signal line of the sixth transistor T6 of a previous stage, which not only can reduce a capacitance of the first node N1, avoid the first node N1 from being influenced by the light emitting signal line, but also reduce the quantity of light emitting signal lines, which is beneficial to realization of high resolution.

In the display substrate of the present embodiment, a fifth gate electrode and a sixth gate electrode are provided in the first conductive layer, a light emitting signal line is provided in the third conductive layer, the light emitting signal line is connected to the sixth gate electrode through a via, and a light emitting signal connection line is provided in the fourth conductive layer, a first end of the light emitting signal connection line is connected to the light emitting signal line in the present unit row, a second end of the light emitting signal connection line is connected to the fifth gate electrode in the next unit row, and a cascaded light emitting control signal is transferred using the light emitting signal connection line located in the SD2 layer, and the first power supply line of the SD3 layer shields the light emitting signal connection line, effectively stabilizing a potential of the light emitting signal.

The display substrate of the present disclosure forms a net-like connecting structure by providing a third connection line whose main body portion extends along the first direction and a second power supply line whose main body portion extends along the second direction, which not only effectively reduces the resistance of the second power supply line and reduces the voltage drop of the second power supply voltage, but also effectively improves the uniformity of the second power supply voltage in the display substrate, effectively improves the display uniformity, and improves the display effect and the display quality.

The display substrate of the present disclosure adopts a 3SD mode and adds a first capacitor, and respectively forms a net-like connecting structure for a second power supply signal, a net-like connecting structure for a first initial signal, and a net-like connecting structure for a second initial signal on the display substrate, thereby further improving the display effect.

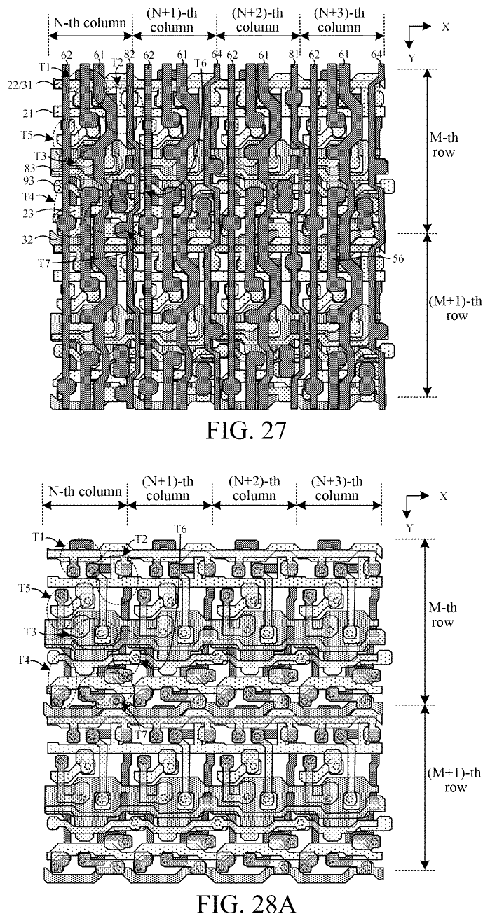

FIG. 27 is a schematic diagram of a structure of another display substrate according to an exemplary embodiment of the present disclosure, and illustrates a planar structure of eight circuit units (2 unit rows and 4 unit columns). In an exemplary implementation, a main structure of the display substrate of the present embodiment is substantially the same as that shown in FIG. 17, except that the display substrate of the present embodiment has a 2SD structure.

In an exemplary implementation, the plurality of conductive layers may at least include a first conductive layer, a second conductive layer, a third conductive layer, and a fourth conductive layer sequentially disposed on the base substrate along a direction away from the base substrate, the fifth gate electrode and the sixth gate electrode may be disposed in the first conductive layer, the third connection line 83 and the light emitting signal line 93 may be disposed in the third conductive layer, and the light emitting signal connection line 56, the first power supply line 61, the data signal line 62, the second power supply line 64, the first connection line 81, and the second connection line 82 may be disposed in the fourth conductive layer.

In an exemplary embodiment, taking eight circuit units (two unit rows and fourth unit columns) as an example, the manufacturing process for the display substrate of the present embodiment may include the following operations.

(31) A pattern of a semiconductor layer is formed, and the process of forming the pattern of the semiconductor layer and the structure of the semiconductor layer are substantially the same as those shown in FIG. 18.

(32) A pattern of a first conductive layer is formed, and the process of forming the pattern of the first conductive layer, and the structure of the first conductive layer are substantially the same as those shown in FIGS. 19A and 19B.

(33) A pattern of a second conductive layer is formed, and the process of forming the pattern of the second conductive layer and the structure of the second conductive layer are substantially the same as those shown in FIGS. 20A and 20B.

(34) A pattern of a fourth insulation layer is formed, and the process of forming the pattern of the fourth insulation layer and the structure of the plurality of vias are substantially the same as those shown in FIG. 21.

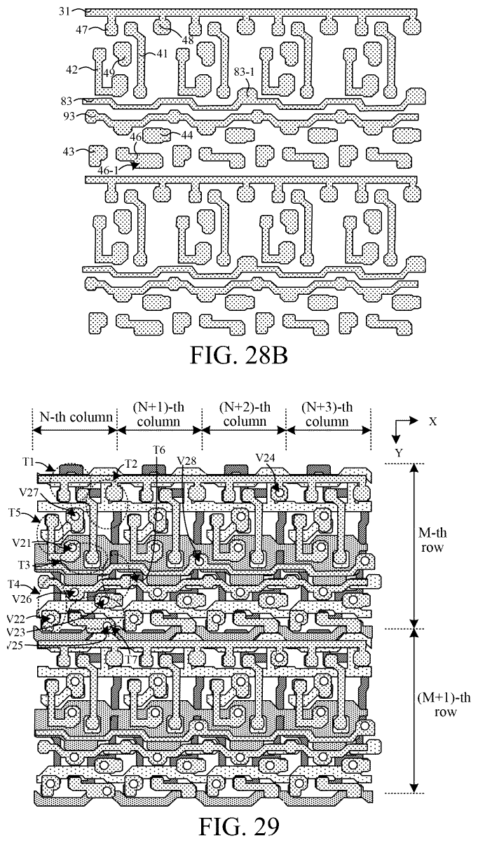

(35) A pattern of a third conductive layer is formed, the process of forming the third conductive layer, and the structure of the third conductive layer are substantially the same as those shown in FIGS. 22A and 22B, except that the third conductive layer is further provided with a third connection line 83, as shown in FIGS. 28A and 28B, and FIG. 28B is a schematic plan view of the third conductive layer in FIG. 28A.

In an exemplary implementation, the third conductive layer in each circuit unit may at least include a first initial signal line 31, a first connection electrode 41, a second connection electrode 42, a third connection electrode 43, a fourth connection electrode 44, a sixth connection electrode 46, a seventh connection electrode 47, an eighth connection electrode 48, a ninth connection electrode 49, a third connection line 83, and a light emitting signal line 93, and the structures of the first initial signal line 31, the light emitting signal line 93, the first connection electrode 41 to the fourth connection electrode 44, and the sixth connection electrode 46 to the ninth connection electrode 49 are substantially the same as those of the foregoing embodiments.

In an exemplary implementation, the third connection line 83 may be in a shape of a straight line or a bending line extending along the first direction X, the third connection line 83 may be located between the first scan signal line 21 and the light emitting signal line 93, and the third connection line 83 is configured to be connected to a second power supply line to be formed subsequently.

In an exemplary implementation, a side of the third connection line 83 close to the first scan signal line 21 is connected to a second power supply connection block 83-1, the second power supply connection block 83-1 may be in a shape of a block (such as a rectangle), and the second power supply connection block 83-1 is configured to be connected to the second power supply line to be formed subsequently. In an exemplary implementation, the second power supply connection block 83-1 may be provided in the circuit units of the (N+1)-th unit column and the (N+3)-th unit column.

In an exemplary implementation, an orthographic projection of the third connection line 83 on the base substrate is at least partially overlapped with an orthographic projection of the second plate 72 on the base substrate, and the orthographic projection of the third connection line 83 on the base substrate is not overlapped with orthographic projections of the first connection electrode 41 and the second connection electrode 42 on the base substrate.

(36) A pattern of a first planarization layer is formed. In an exemplary implementation, forming the pattern of the first planarization layer may include coating a first planarization thin film on the base substrate on which the above-mentioned patterns are formed, patterning the first planarization thin film through a patterning process, to form a first planarization layer covering the third conductive layer, wherein the first planarization layer is provided with a plurality of vias, as shown in FIG. 29.

In an exemplary implementation, the plurality of vias on the first planarization layer at least includes a twenty-first via V21, a twenty-second via V22, a twenty-third via V23, a twenty-fourth via V24, a twenty-fifth via V25, a twenty-sixth via V26, a twenty-seventh via V27, and a twenty-eighth via V28.

In an exemplary implementation, an orthographic projection of the twenty-first via V21 on the base substrate is within a range of an orthographic projection of the first power supply connection block 42-1 on the base substrate, the first planarization layer within the twenty-first via V21 is removed to expose a surface of the first power supply connection block 42-1, and the twenty-first via V21 is configured such that the first power supply line to be formed subsequently is connected to a first power supply connection block 42-1 through the twenty-first via V21. In an exemplary implementation, the twenty-first via V21 may be provided in each circuit unit.

In an exemplary implementation, an orthographic projection of the twenty-first via V21 on the base substrate may be within a range of an orthographic projection of the second plate 72 on the base substrate.

In an exemplary implementation, an orthographic projection of the twenty-second via 22 on the base substrate is within a range of an orthographic projection of the third connection electrode 43 on the base substrate, the first planarization layer within the twenty-second via V22 is removed to expose a surface of the third connection electrode 43, and the twenty-second via V22 is configured such that a data signal line to be formed subsequently is connected to the third connection electrode 43 through the twenty-second via V22. In an exemplary implementation, the twenty-second via V22 may be provided in each circuit unit.

In an exemplary implementation, an orthographic projection of the twenty-third via V23 on the base substrate is within a range of an orthographic projection of the fourth connection electrode 44 on the base substrate, the first planarization layer within the twenty-third via V23 is removed to expose a surface of the fourth connection electrode 44, and the twenty-third via V23 is configured such that an anode connection electrode to be formed subsequently is connected to the fourth connection electrode 44 through the twenty-third via V23. In an exemplary implementation, the twenty-third via V23 may be provided in each circuit unit.

In an exemplary implementation, an orthographic projection of the twenty-fourth via V24 on the base substrate is within a range of an orthographic projection of the eighth connection electrode 48 on the base substrate, the first planarization layer within the twenty-fourth via V24 is removed to expose a surface of the eighth connection electrode 48, and the twenty-fourth via V24 is configured such that a first connection line to be formed subsequently is connected to the eighth connection electrode 48 through the twenty-fourth via V24. In an exemplary implementation, the twenty-fourth via V24 may be provided in the circuit units of the (N+2)-th unit column.

In an exemplary implementation, an orthographic projection of the twenty-fifth via V25 on the base substrate is within a range of an orthographic projection of the initial connection block 46-1 on the base substrate, the first planarization layer within the twenty-fifth via V25 is removed to expose a surface of the initial connection block 46-1, and the twenty-fifth via V25 is configured such that the second connection line to be formed subsequently is connected to the initial connection block 46-1 through the twenty-fifth via V25. In an exemplary implementation, the twenty-fifth via V25 may be provided in the circuit units of the N-th unit column.

In an exemplary implementation, an orthographic projection of the twenty-sixth via V26 on the base substrate is within a range of an orthographic projection of the light emitting connection block 93-1 of the light emitting signal line 93 on the base substrate, the first planarization layer within the twenty-sixth via V26 is removed to expose a surface of the light emitting connection block 93-1, and the twenty-sixth via V26 is configured such that a light emitting signal connection line to be formed subsequently is connected to the light emitting connection block 93-1 through the twenty-sixth via V26. In an exemplary implementation, the twenty-sixth via V26 may be provided in each circuit unit.

In an exemplary implementation, an orthographic projection of the twenty-seventh via V27 on the base substrate is within a range of an orthographic projection of the ninth connection electrode 49 on the base substrate, the first planarization layer within the twenty-seventh via V27 is removed to expose a surface of the ninth connection electrode 49, and the twenty-seventh via V27 is configured such that the light emitting signal connection line to be formed subsequently is connected to the ninth connection electrode 49 through the twenty-seventh via V27. In an exemplary implementation, the twenty-seventh via V27 may be provided in each circuit unit.

In an exemplary implementation, an orthographic projection of the twenty-eighth via V28 on the base substrate is within a range of an orthographic projection of the second power supply connection block 83-1 of the third connection line 83 on the base substrate, the first planarization layer within the twenty-eighth via V28 is removed to expose a surface of the second power supply connection block 83-1, and the twenty-eighth via V28 is configured such that the second power supply line to be formed subsequently is connected to the second power supply connection block 83-1 through the twenty-eighth via V28. In an exemplary implementation, the twenty-eighth via V28 may be provided in the circuit units of the (N+1)-th unit column and the (N+3)-th unit column.

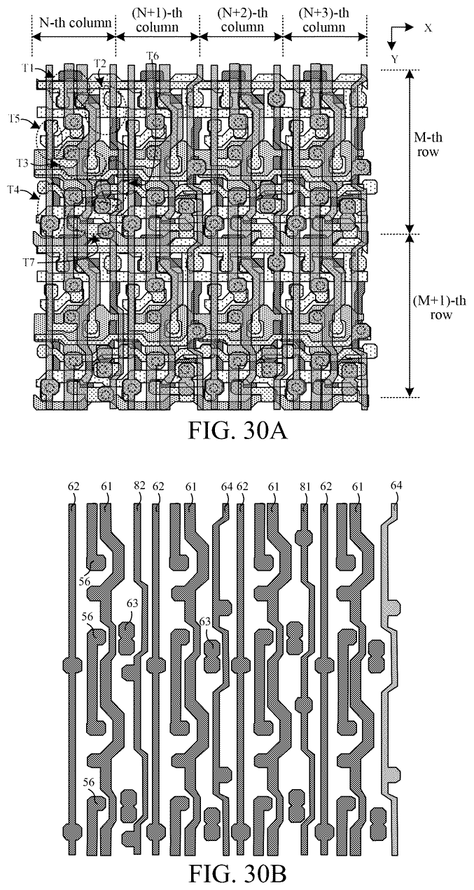

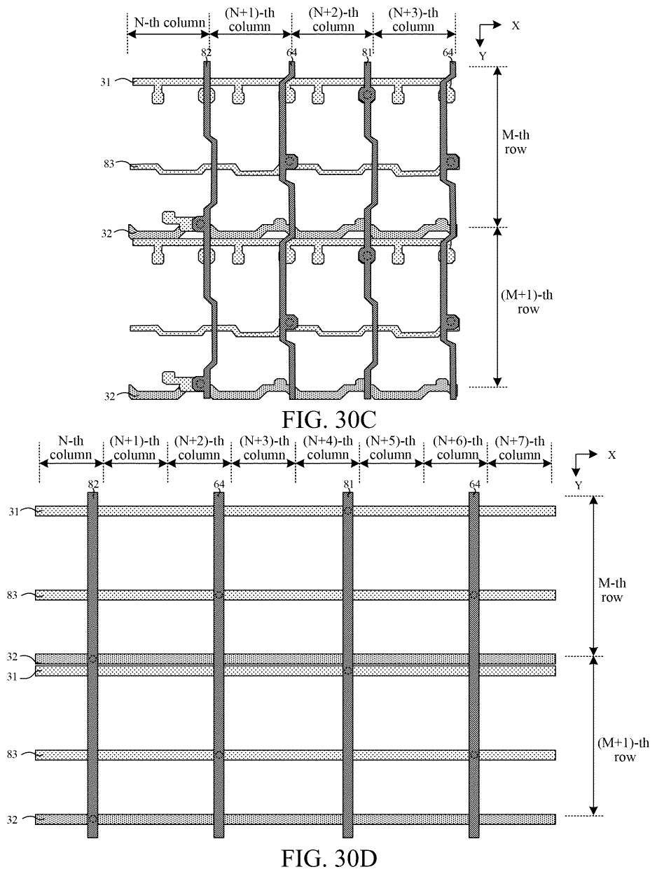

(37) A pattern of a fourth conductive layer is formed. In an exemplary implementation, forming the pattern of the fourth conductive layer may include: depositing a fourth conductive thin film on the base substrate on which the aforementioned patterns are formed, and patterning the fourth conductive thin film by a patterning process to form the fourth conductive layer arranged on the first planarization layer, as shown in FIG. 30A and FIG. 30B, FIG. 30B is a schematic planar diagram of the fourth conductive layer in FIG. 30A.

In an exemplary implementation, the fourth conductive layer at least includes a light emitting signal connection line 56, a first power supply line 61, a data signal line 62, an anode connection electrode 63, a second power supply line 64, a first connection line 81, and a second connection line 82.

In an exemplary implementation, the light emitting signal connection line 56 may be in a shape of a strip extending along the second direction Y, a first end of the light emitting signal connection line 56 is connected to the light emitting connection block 93-1 of the circuit unit in the present unit row through the twenty-sixth via V26, a second end of the light emitting signal connection line 56 extends along the second direction Y to the circuit unit in the next unit row, and is connected to a ninth connection electrode 49 of the circuit unit in the next unit row through the twenty-seventh via V27. In an exemplary implementation, the light emitting signal connection line 56 may be provided in each circuit unit.

In an exemplary implementation, since the light emitting connection block 93-1 of the circuit unit in the present unit row is connected to the light emitting signal line 93 in the present unit row and a ninth connection electrode 49 of the circuit unit in the next unit row is connected to the fifth gate electrode 25 of that circuit unit, the light emitting signal connection line 56 thus realizes connection between the light emitting signal line 93 in the present unit row and the fifth gate electrode 25 in the next unit row, the light emitting signal line 93 in present unit row can control not only turn-on and turn-off of the sixth transistor T6 in present unit row, but also turn-on and turn-off of a fifth transistor T5 in the next unit row, i.e., in the circuit unit of the presents unit row, the fifth transistor T5 is controlled by a light emitting signal line 93 of the previous unit row, and the sixth transistor T6 is controlled by the light emitting signal line 93 of the presents unit row.

In an exemplary implementation, the first power supply line 61 may be in a shape of a straight line or a bending line extending along the second direction Y, and the first power supply line 61 is connected to the first power supply connection block 42-1 through the twenty-first via V21. Since the first power supply connection block 42-1 is connected to the second connection electrode 42, and the second connection electrode 42 is connected to the first electrode of the fifth transistor T5, the second plate 72 of the storage capacitor, and the fourth plate 74 of the first capacitor, the first power supply line 61 can write the first power supply signal to the first electrode of the fifth transistor T5, the second plate 72 of the storage capacitor, and the fourth plate 74 of the first capacitor. In an exemplary implementation, the first power supply line 61 may be provided in each circuit unit.

In an exemplary implementation, the data signal line 62 may be in a shape of a straight line or a bending line extending along the second direction Y, and the data signal line 62 is connected to the third connection electrode 43 through the twenty-second via V22. Since the third connection electrode 43 is connected to the first region of the fourth active layer, the connection of the data signal line 62 to the first electrode of the fourth transistor T4 is realized, the data signal line 62 can write a data signal to the first electrode of the fourth transistor T4. In an exemplary implementation, the data signal line 62 may be provided in each circuit unit.

In an exemplary implementation, the anode connection electrode 63 may be in a shape of a strip extending along the first direction X or the second direction Y, the anode connection electrode 63 is connected to the fourth connection electrode 44 through the twenty-third via V23, and the anode connection electrode 63 is configured to be connected to the anode to be formed subsequently. Since the fourth connection electrode 44 is connected to the second region of the sixth active layer and a second region of the seventh active layer, connection between the anode to be formed subsequently and the second electrode of the sixth transistor T6 as well as the second electrode of the seventh transistor T7 can be achieved, and the pixel drive circuit can drive the light emitting device to emit light. In an exemplary implementation, the anode connection electrode 63 may be provided in each circuit unit.

In an exemplary implementation, the second power supply line 64 may be in a shape of a straight line or a bending line extending along the second direction Y, and the second power supply line 64 is connected to the second power supply connection block 83-1 through the twenty-eighth via V28. Since the second power supply connection block 83-1 is connected to the third connection line 83, interconnection between the third connection line 83 whose main body portion extends along the first direction X and the second power supply line 64 whose main body portion extends along the second direction Y is realized, and a net-like connecting structure is formed on the display substrate. In an exemplary implementation, the second power supply line 64 may be provided in the circuit units of the (N+1)-th unit column and the (N+3)-th unit column.

In an exemplary implementation, an orthographic projection of the second power supply line 64 on the base substrate is not overlapped with an orthographic projection of the gate electrode of the third transistor (i.e., the first plate) on the base substrate.

In an exemplary implementation, an orthographic projection of the second power supply line 64 on the base substrate and an orthographic projection of the active connection line 18 in the semiconductor layer connecting the second active layer and the third active layer on the base substrate are at least partially not overlapped.

In an exemplary implementation, the first connection line 81 may be in a shape of a straight line or a bending line extending along the second direction Y, and the first connection line 81 is connected to the eighth connection electrode 48 through the twenty-fourth via V24. Since the eighth connection electrode 48 is connected to the first initial signal line 31, interconnection between the first initial signal line 31 whose main body portion extends along the first direction X and the first connection line 81 whose main body portion extends along the second direction Y is realized, and a net-like connecting structure is formed on the display substrate. In an exemplary implementation, the first connection line 81 may be provided in the circuit units of the (N+2)-th unit column.

In an exemplary implementation, an orthographic projection of the first connection line 81 on the base substrate is not overlapped with an orthographic projection of the gate electrode of the third transistor (i.e. the first plate) on the base substrate.

In an exemplary implementation, an orthographic projection of the first connection line 81 on the base substrate and an orthographic projection of the active connection line 18 in the semiconductor layer connecting the second active layer and the third active layer on the base substrate are at least partially not overlapped.

In an exemplary implementation, the second connection line 82 may be in a shape of a straight line or a bending line extending along the second direction Y, and the second connection line 82 is connected to the initial connection block 46-1 through the twenty-fifth via V25. Since the initial connection block 46-1 is connected to the sixth connection electrode 46, and the sixth connection electrode 46 is connected to the second initial signal line 32, the interconnection between the second initial signal line 32 whose main body portion extends along the first direction X and the second connection line 82 whose main body portion extends along the second direction Y is realized, and a net-like connecting structure is formed on the display substrate. In an exemplary implementation, the second connection line 82 may be provided in the circuit units of the N-th unit column.

In an exemplary implementation, an orthographic projection of the second connection line 82 on the base substrate is not overlapped with an orthographic projection of the gate electrode of the third transistor (i.e., the first plate) on the base substrate.

In an exemplary implementation, the orthographic projection of the second connection line 82 on the base substrate and an orthographic projection of the active connection line 18 in the semiconductor layer connecting the second active layer and the third active layer on the base substrate are at least partially not overlapped.

FIGS. 30C and 30D are schematic diagrams of another net-like connecting structure for an initial signal and a net-like connecting structure for a second power supply according to an exemplary embodiment of the present disclosure. As shown in FIG. 30C, the first initial signal line 31, the second initial signal line 32, and the third connection line 83 may be provided in each unit row, and the first connection line 81, the second power supply line 64, the second connection line 82, and the second power supply line 64 may be alternately provided in four consecutive unit columns. For example, the N-th unit column may be provided with a second connection line 82, the (N+1)-th unit column may be provided with a second power supply line 64, the (N+2)-th unit column may be provided with a first connection line 81, and the (N+3)-th unit column may be provided with a second power supply line 64. As shown in FIG. 30D, the first initial signal line 31, the second initial signal line 32, and the third connection line 83 may be provided in each unit row, and the first connection line 81, the second power supply line 64, the second connection line 82, and the second power supply line 64 may be alternately provided in eight consecutive unit columns. For example, the N-th unit column may be provided with a second connection line 82, the (N+2)-th unit column may be provided with a second power supply line 64, the (N+4)-th unit column may be provided with a first connection line 81, the (N+5)-th unit column may be provided with a second power supply line 64, and the (N+1)-th unit column, the (N+3)-th unit column, the N+5-th unit column, and the N+7-th unit column are not provided with a first connection line, a second connection line, and a second power supply line, which is not limited in the present disclosure.

(38) A pattern of a second planarization layer is formed. In an exemplary implementation, forming the pattern of the second planarization layer may include: coating a second planarization thin film on the base substrate on which the above-mentioned patterns are formed, patterning the second planarization thin film by a patterning process, forming a second planarization layer covering the fourth conductive layer, and the second planarization layer is provided with a plurality of anode vias, and an anode via is configured such that the anode to be formed subsequently is connected to the anode connection electrode through the vias.

In an exemplary implementation, after the drive circuit layer is prepared, a light emitting structure layer is prepared on the drive circuit layer first, and then an encapsulation structure layer is formed, which is not repeated here.

The display substrate provided in the present embodiment also realizes separate control of the fifth transistor and the sixth transistor, and can realize pulse width modulation with a higher accuracy at an ultra-high frequency, light emitting signal duty compensation, low gray scale compensation, and improved afterimage. In at least one circuit unit of the present embodiment, the sixth transistor T6 is controlled by the light emitting signal line of the present unit row, and the fifth transistor T5 is controlled by a light emitting signal line of the previous unit row, that is, the fifth transistor T5 adopts the (cascaded) mode of being driven by the light emitting signal line of the sixth transistor T6 of a previous stage, which not only can reduce capacitance of the first node N1, avoid the first node N1 from being influenced by the light emitting signal line, but also reduce the quantity of light emitting signal lines, which is beneficial to the realization of high resolution.

The display substrate of the present embodiment adopts a 2SD mode and adds a first capacitor, and respectively forms a net-like connecting structure for a second power supply signal, a net-like connecting structure for a first initial signal, and a net-like connecting structure for a second initial signal on the display substrate, thereby further improving the display effect.

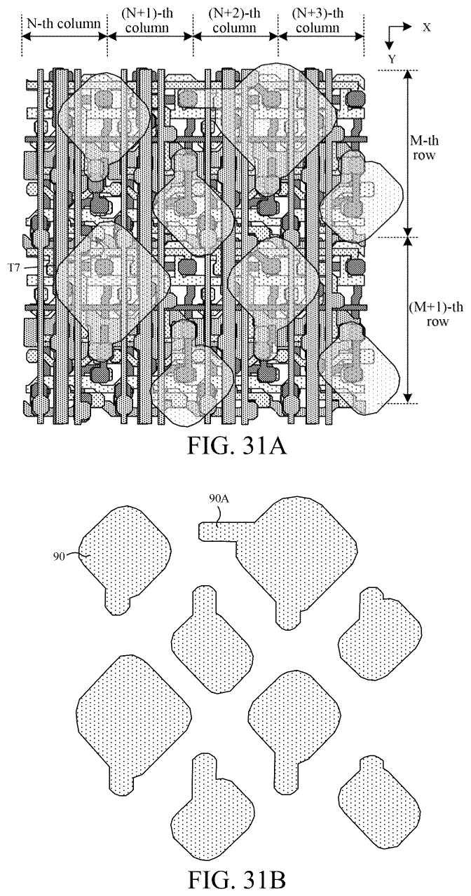

FIG. 31A and FIG. 31B are schematic diagrams of another display substrate after a pattern of an anode conductive layer is formed according to the present disclosure, and FIG. 31B is a schematic plan view of the anode conductive layer in FIG. 31A. For the display substrate of the foregoing embodiments, since the dummy-pad is provided in the third conductive layer or the fourth conductive layer, consistency of the film layers in each sub-pixel can be ensured by providing auxiliary electrodes in the anode conductive layer.

In an exemplary implementation, taking the display substrate shown in FIG. 17 as an example, the anode conductive layer may include a plurality of anodes 90, each anode 90 may be connected to an anode connection electrode of a corresponding circuit unit through an anode via, and at least one anode 90 may be provided with an auxiliary electrode 90A. A first end of the auxiliary electrode 90A is connected to the at least one anode 90, a second end of the auxiliary electrode 90A extends in a direction away from the at least one anode 90, and an orthographic projection of the auxiliary electrode 90A on the base substrate is at least partially overlapped with an orthographic projection of the fourteenth connection electrode as a dummy-pad on the base substrate, as shown in FIGS. 31A and 31B. Illustration is given in FIGS. 31A and 31B just by taking a case in which one anode 90 is provided with one auxiliary electrode 90A as an example. In fact, auxiliary electrodes 90A may be provided on a plurality of anodes 90 respectively, and a plurality of auxiliary electrodes 90A may be at least partially overlapped with a plurality of dummy-pads, respectively, or a plurality of auxiliary electrodes 90A may be provided on one anode 90, which is not limited in the present disclosure. In the present disclosure, by providing an auxiliary electrode on at least one anode, the consistency of film layers in each sub-pixel can be ensured, and visualization defects can be reduced.

In an exemplary implementation, the anode 90 and the auxiliary electrode 90A may be of an interconnected integral structure.

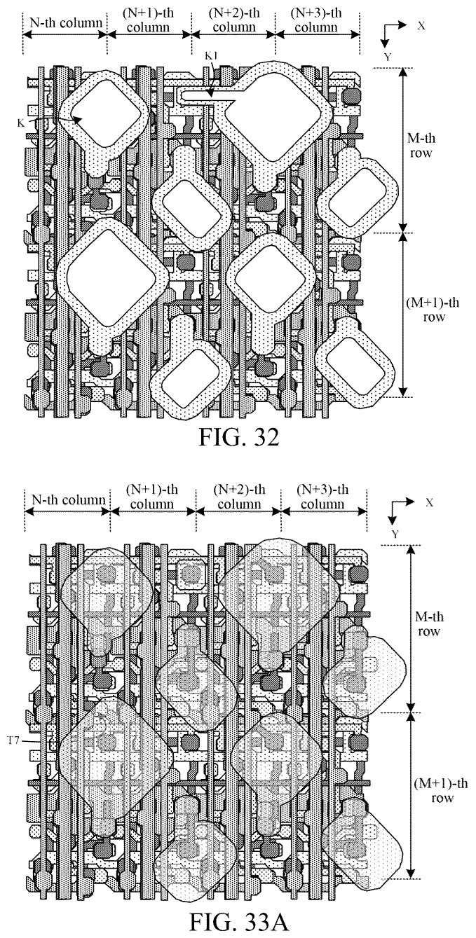

FIG. 32 is a schematic diagram of yet another display substrate after a pattern of a pixel definition layer is formed according to the present disclosure. As shown in FIG. 32, the pixel definition layer may include a plurality of pixel openings K, each of which may expose a surface of the anode, and at least one pixel opening K may be connected to a sub-opening K1, which may expose a surface of the auxiliary electrode.

In an exemplary implementation, a pixel opening K and a sub-opening K1 may communicate with each other.

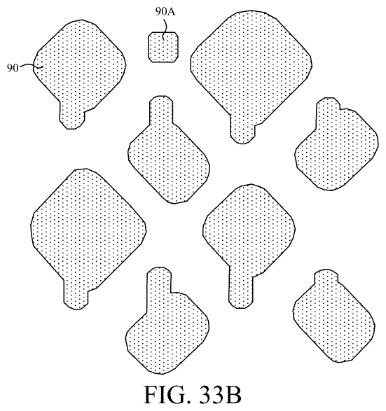

FIG. 33A and FIG. 33B are schematic diagrams of another display substrate after a pattern of an anode conductive layer is formed according to the present disclosure, and FIG. 33B is a schematic plan view of the anode conductive layer in FIG. 33A. The structure of the anode conductive layer of the present embodiment is substantially the same as that shown in FIGS. 31A and 31B, except that the auxiliary electrode 90A is provided separately, that is, the anode 90 is not connected to the auxiliary electrode 90A.

In an exemplary implementation, taking the display substrate shown in FIG. 17 as an example, the anode conductive layer may include a plurality of anodes 90 and at least one auxiliary electrode 90A, each anode 90 may be connected to an anode connection electrode of a corresponding circuit unit through an anode via, and an orthographic projection of the auxiliary electrode 90A on the base substrate is at least partially overlapped with an orthographic projection of the fourteenth connection electrode as a dummy-pad on the base substrate, as shown in FIGS. 33A and 33B. Illustration is given in FIGS. 33A and 33B just by taking a case in which the anode conductive layer is provided with one auxiliary electrode 90A as an example. In fact, the anode conductive layer may be provided with a plurality of auxiliary electrodes 90A, the plurality of auxiliary electrodes 90A are at least partially overlapped with a plurality of dummy-pads, and the auxiliary electrodes 90A may be provided in a floating state. In a subsequent formation of the pixel definition layer, No sub-opening is provided at a position where the auxiliary electrode 90A is located, which is not limited in the present disclosure. In the present disclosure, by providing at least one auxiliary electrode in the anode conductive layer, consistency of film layers in each sub-pixel can be ensured, and visualization defects can be reduced.

In an exemplary implementation, the provision of an auxiliary electrode in the anode conductive layer can be applied in the structure of the display substrate shown in FIGS. 5 and 27, which is not limited in the present disclosure.

The aforementioned structure shown in the present disclosure and the manufacturing process thereof are merely exemplary description. In an exemplary implementation, corresponding structures may be changed and patterning processes may be added or reduced according to actual needs, which is not limited here in the present disclosure.

In an exemplary implementation, the display substrate according to the present disclosure may be applied to a display apparatus with a pixel drive circuit, such as an OLED, a quantum dot display (QLED), a light emitting diode display (Micro LED or Mini LED), or a Quantum Dot Light Emitting Diode display (QDLED), which is not limited here in the present disclosure.

The present disclosure further provides a display apparatus which includes the aforementioned display substrate. The display apparatus may be any product or component with a display function, such as a mobile phone, a tablet computer, a television, a display, a laptop computer, a digital photo frame, or a navigator, which is not limited in the embodiments of the present disclosure.

Although implementations disclosed in the present disclosure are as above, it should be noted that the above implementations are exemplary only rather than restrictive. Therefore, the present disclosure is not limited to what is specifically shown and described herein. Various modifications, substitutions or omissions may be made in forms and details of implementations without departing from the scope of the present disclosure.

1. A display substrate comprising a plurality of circuit units constituting a plurality of unit rows and a plurality of unit columns, at least one circuit unit comprises a pixel drive circuit and at least one control line configured to provide a light emitting control signal to the pixel drive circuit; in at least one circuit unit, the pixel drive circuit at least comprises a drive transistor, a first light emitting control transistor, and a second light emitting control transistor, wherein a first electrode of the first light emitting control transistor is connected to a first power supply line, a second electrode of the first light emitting control transistor is connected to a first electrode of the drive transistor, and a first electrode of the second light emitting control transistor is connected to a second electrode of the drive transistor; the first light emitting control transistor and the second light emitting control transistor are connected to different control lines, and the first light emitting control transistor and the second light emitting control transistor are respectively disposed at two sides of the drive transistor in a unit column direction.

2. The display substrate according to claim 1, wherein the at least one control line comprises a first signal line and a second signal line, and the first light emitting control transistor is connected to the first signal line and the second light emitting control transistor is connected to the second signal line, and the first signal line and the second signal line are respectively disposed at two sides of the drive transistor in the unit column direction.

3. The display substrate according to claim 2, wherein the display substrate comprises a plurality of conductive layers in a direction perpendicular to the display substrate, and the first signal line and the second signal line are disposed in different conductive layers.

4. The display substrate according to claim 3, wherein the second light emitting control transistor at least comprises a second gate, the second gate and the first signal line are disposed in a same conductive layer, and the second gate and the second signal line are disposed in different conductive layers.

5. The display substrate according to claim 2, wherein the pixel drive circuit further comprises a compensation transistor, a gate electrode of the compensation transistor is connected to a first scan signal line, a first electrode of the compensation transistor is connected to a gate electrode of the drive transistor through a first connection electrode, and a second electrode of the compensation transistor is connected to the second electrode of the drive transistor and the first electrode of the second light emitting control transistor respectively; an orthographic projection of the first connection electrode on a plane of the display substrate is at least partially overlapped with an orthographic projection of the first signal line on the plane of the display substrate, and the orthographic projection of the first connection electrode on the plane of the display substrate is at least partially overlapped with an orthographic projection of the first scan signal line on the plane of the display substrate.

6. The display substrate according to claim 5, wherein the compensation transistor at least comprises a compensation active layer, the second light emitting control transistor at least comprises a second light emitting control active layer, and a second region of the compensation active layer is connected to a first region of the second light emitting control active layer through a fifth connection electrode; in a direction perpendicular to the display substrate, the display substrate at least comprises at least one semiconductor layer and at least one conductive layer, the compensation active layer and the second light emitting control active layer are disposed in the semiconductor layer, and the fifth connection electrode is disposed in the conductive layer; or
wherein the pixel drive circuit further comprises a data writing transistor, a first electrode of the data writing transistor is connected to a data signal line, a second electrode of the data writing transistor is connected to the first electrode of the drive transistor, and the data writing transistor and the compensation transistor are respectively disposed at two sides of the drive transistor in the unit column direction.

7. (canceled)

8. The display substrate according to claim 1, wherein the at least one control line comprises a light emitting signal line, the light emitting signal line is connected to a second light emitting control transistor in a present unit row, and the light emitting signal line is connected to a first light emitting control transistor in a next unit row.

9. The display substrate according to claim 8, wherein the first light emitting control transistor at least comprises a first gate, the second light emitting control transistor at least comprises a second gate, the light emitting signal line is connected to the second gate of the second light emitting control transistor in the present unit row, and the light emitting signal line is connected to the first light emitting control transistor in the next unit row through a light emitting signal connection line.

10. The display substrate according to claim 9, wherein in a direction perpendicular to the display substrate, the display substrate comprises a plurality of conductive layers, the first gate of the first light emitting control transistor and the second gate of the second light emitting control transistor are disposed in a same conductive layer, the first gate and the light emitting signal line are disposed in different conductive layers, the first gate and the light emitting signal connection line are disposed in different conductive layers, and the light emitting signal connection line and the light emitting signal line are disposed in different conductive layers.

11. The display substrate according to claim 10, wherein the plurality of conductive layers at least comprises a first conductive layer, a second conductive layer, a third conductive layer, and a fourth conductive layer disposed sequentially on a base substrate along a direction away from the base substrate, the first gate and the second gate are disposed in the first conductive layer, the light emitting signal line is disposed in the third conductive layer, the light emitting signal line is connected to the second gate through a via, the light emitting signal connection line is disposed in the fourth conductive layer, a first end of the light emitting signal connection line is connected to the light emitting signal line in the present unit row through a via, and a second end of the light emitting signal connection line is connected to the first gate in the next unit row through a via.

12. The display substrate according to claim 11, wherein the plurality of conductive layers further comprises a fifth conductive layer disposed on a side of the fourth conductive layer away from the base substrate, the first power supply line is disposed in the fifth conductive layer, and an orthographic projection of the first power supply line on a plane of the display substrate is at least partially overlapped with an orthographic projection of the light emitting signal connection line on the plane of the display substrate.

13. The display substrate according to claim 1, wherein the at least one circuit unit further comprises a first initial signal line extending along a unit row direction and a first connection line extending along the unit column direction, the first initial signal line is configured to provide a first initial signal to the pixel drive circuit, the first initial signal line and the first connection line are connected to form a net-like connecting structure for transmitting the first initial signal.

14. The display substrate according to claim 13, wherein an orthographic projection of the first connection line on a plane of the display substrate is not overlapped with an orthographic projection of a gate electrode of the drive transistor on the plane of the display substrate; or
wherein the pixel drive circuit further comprises a compensation transistor, an active layer of the compensation transistor and an active layer of the drive transistor are connected to each other by an active connection line, an orthographic projection of the first connection line on the plane of the display substrate and an orthographic projection of the active connection line on the plane of the display substrate are at least partially not overlapped.

15. (canceled)

16. The display substrate according to claim 1, wherein the at least one circuit unit further comprises a second initial signal line extending along a unit row direction and a second connection line extending along the unit column direction, the second initial signal line is configured to provide a second initial signal to the pixel drive circuit, the second initial signal line and the second connection line are connected to form a net-like connecting structure for transmitting the second initial signal.

17. The display substrate according to claim 16, wherein an orthographic projection of the second connection line on a plane of the display substrate is not overlapped with an orthographic projection of a gate electrode of the drive transistor on the plane of the display substrate; or
wherein the pixel drive circuit further comprises a compensation transistor, an active layer of the compensation transistor and an active layer of the drive transistor are connected to each other by an active connection line, an orthographic projection of the second connection line on a plane of the display substrate and an orthographic projection of the active connection line on the plane of the display substrate are at least partially not overlapped.

18. (canceled)

19. The display substrate according to claim 1, wherein the at least one circuit unit further comprises a third connection line extending along a unit row direction and a second power supply line extending along the unit column direction, and the second power supply line and the third connection line are connected to form a net-like connecting structure for transmitting a second power supply signal.

20. The display substrate according to claim 19, wherein an orthographic projection of the second power supply line on a plane of the display substrate is not overlapped with an orthographic projection of a gate electrode of the drive transistor on the plane of the display substrate; or
wherein the pixel drive circuit further comprises a compensation transistor, an active layer of the compensation transistor and an active layer of the drive transistor are connected to each other by an active connection line, and an orthographic projection of the second power supply line on a plane of the display substrate and an orthographic projection of the active connection line on the plane of the display substrate are at least partially not overlapped.

21. (canceled)

22. The display substrate of claim 1, wherein the pixel drive circuit further comprises a storage capacitor and a first capacitor; the storage capacitor comprises a first plate and a second plate, an orthographic projection of the first plate on a plane of the display substrate is at least partially overlapped with an orthographic projection of the second plate on the plane of the display substrate, the first plate serves as a gate electrode of the drive transistor, and the second plate is connected to the first power supply line; the first capacitor comprises a third plate and a fourth plate, an orthographic projection of the third plate on the plane of the display substrate is at least partially overlapped with an orthographic projection of the fourth plate on the plane of the display substrate, the third plate is respectively connected to the first electrode of the drive transistor and the second electrode of the first light emitting control transistor, and the fourth plate is connected to the first power supply line.

23. The display substrate according to claim 22, wherein in a direction perpendicular to the display substrate, the display substrate at least comprises a semiconductor layer, a first conductive layer, and a second conductive layer disposed sequentially on the base substrate along a direction away from the base substrate, the third plate is disposed in the semiconductor layer, the first plate is disposed in the first conductive layer, and the second plate and the fourth plate are disposed in the second conductive layer.

24. A display apparatus, comprising a display substrate according to claim 1.
